(19) United States
(12) Patent Application Publication
(10) Pub. No.: US 2024/0047616 A1
(43) Pub. Date: Feb. 8, 2024

(54) DISPLAY DEVICE AND METHOD OF MANUFACTURING THE SAME

(71) Applicant: LG Display Co., Ltd., Seoul (KR)

(72) Inventors: YoungIn JANG, Seoul (KR); Soyoung LEE, Seoul (KR); HyunGon KIM, Seoul (KR)

(73) Assignee: LG Display Co., Ltd., Seoul (KR)

(21) Appl. No.: 18/224,782

(22) Filed: Jul. 21, 2023

(30) Foreign Application Priority Data
Aug. 2, 2022 (KR) 10-2022-0096006

(51) Int. Cl. H01L 33/38; H01L 33/62; H01L 25/075

(52) U.S. Cl. CPC H01L 33/382; H01L 33/62; H01L 25/0753; H01L 2933/0066; H01L 2933/0016

(57) ABSTRACT

According to an aspect of the present disclosure, a display device includes a substrate in which a plurality of sub-pixels is defined, a light emitting element disposed on each of the plurality of sub-pixels, and a first connection electrode surrounding a first semiconductor layer disposed at a lower part of the light emitting element, a second connection electrode in contact with a top surface of the light emitting element, a first planarization layer disposed between the first connection electrode and the second connection electrode and having a smaller thickness than the first semiconductor layer of the light emitting element, and a second planarization layer disposed between the first planarization layer and the second connection electrode.

### CROSS-REFERENCE TO RELATED APPLICATIONS

This application claims the priority of Korean Patent Application No. 10-2022-0096006 filed on Aug. 2, 2022, in the Korean Intellectual Property Office, the disclosure of which is incorporated herein by reference.

### BACKGROUND

### Technical Field

The present disclosure relates to a display device and a method of manufacturing the same, and more particularly, to a display device using light emitting diodes (LEDs) and a method of manufacturing the same.

### Discussion of the Related Art

Display devices used for a monitor of a computer, a television, or a cellular phone include an organic light emitting display (OLED) device, a liquid crystal display (LCD) device, and the like. The OLED is a self-emitting device, and the LCD requires a separate light source.

Display devices have a wide range of diverse applications, including personal digital assistants, as well as monitors of computers and televisions. A display device with a large display area, and reduced volume and weight is being studied.

Recently, display devices including LEDs are attracting attention as the next generation display device. An LED is made of an inorganic material instead of an organic material, and thus has excellent reliability and a longer lifetime than the LCD or the OLED. Also, the LEDs can be turned on and off quickly, have high luminous efficiency, are robust to impact and stable, and can display a high-brightness image.

### SUMMARY

Accordingly, embodiments of the present disclosure are directed to a display device and a method of manufacturing the same that substantially obviate one or more of the problems due to limitations and disadvantages of the related art.

An aspect of the present disclosure is to provide a display device in which a first connection electrode and a first semiconductor layer of a light emitting element can be self-aligned, and a method of manufacturing the same.

Another aspect of the present disclosure is to provide a display device in which a second connection electrode and a second semiconductor layer of a light emitting element can be self-aligned, and a method of manufacturing the same.

Yet another aspect of the present disclosure is to provide a display device in which a short defect can be reduced or minimized, and a method of manufacturing the same. The short defect may occur due to misalignment between a first connection electrode and a second connection electrode caused by a process error.

Still another aspect of the present disclosure is to provide a display device with improved light efficiency, and a method of manufacturing the same.

Still another aspect of the present disclosure is to provide a display device in which an undercut structure of a light emitting element is separated from a first connection electrode, and a method of manufacturing the same. In the display device, disconnection of the first connection electrode can be minimized.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises a substrate in which a plurality of sub-pixels is defined. Also, the display device includes a light emitting element disposed on each of the plurality of sub-pixels, and a first connection electrode surrounding a first semiconductor layer disposed at a lower part of the light emitting element. Further, the display device includes a second connection electrode in contact with a top surface of the light emitting element. Furthermore, the display device includes a first planarization layer disposed between the first connection electrode and the second connection electrode and having a smaller thickness than the first semiconductor layer of the light emitting element. Moreover, the display device includes a second planarization layer disposed between the first planarization layer and the second connection electrode. The first planarization layer having a smaller thickness than the first semiconductor layer may be used to self-align the first semiconductor layer of the light emitting element with the first connection electrode.

In another aspect, a method of manufacturing a display device comprises a process of transferring a light emitting element on an adhesive layer and a process of forming a metal layer on the light emitting element. Also, the method includes a process of forming a first planarization layer having a smaller thickness than a first semiconductor layer of the light emitting element on the light emitting element and the metal layer. Further, the method includes a process of forming a first connection electrode by etching the metal layer exposed from the first planarization layer. The first planarization layer having a smaller thickness than the first semiconductor layer may be used to partially etch only an emission layer disposed on the first planarization layer and the metal layer surrounding a second semiconductor layer. Thus, the first connection electrode and the first semiconductor layer may be self-aligned and a short defect may be minimized.

Other detailed matters of the exemplary embodiments are included in the detailed description and the drawings.

According to the present disclosure, the first planarization layer is formed to have a smaller thickness than the first semiconductor layer. Thus, the first connection electrode may be formed by self-aligning the first connection electrode and the first semiconductor layer.

According to the present disclosure, the second connection electrode and the second semiconductor layer of the light emitting element are self-aligned by performing an ashing process onto the second planarization layer. Thus, the second connection electrode may be formed.

According to the present disclosure, the ashing process is performed onto the second planarization layer only until a top surface of the second semiconductor layer is exposed. Thus, a short defect of the second connection electrode caused by an alignment error may be minimized.

According to the present disclosure, the first connection electrode and the second connection electrode may be easily self-aligned.

According to the present disclosure, each of the first connection electrode and the second connection electrode are self-aligned on the first semiconductor layer and the second semiconductor layer of the light emitting element. Thus, a short defect of the first connection electrode and the second connection electrode caused by an alignment error may be minimized.

According to the present disclosure, a reflective electrode is formed at a lower part of the light emitting element. Thus, light extraction efficiency may be improved.

According to the present disclosure, an undercut structure at a lower part of the light emitting element is filled. Thus, a disconnection defect of the first connection electrode may be minimized.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a schematic plan view of a display device according to an exemplary embodiment of the present disclosure;

FIG. 2 and FIG. 3 are cross-sectional views of the display device according to an exemplary embodiment of the present disclosure;

FIG. 4A through FIG. 4E are process diagrams for explaining a method of manufacturing the display device according to an exemplary embodiment of the present disclosure;

FIG. 5 is a cross-sectional view of a display device according to another exemplary embodiment of the present disclosure;

FIG. 6A through FIG. 6E are process diagrams for explaining a method of manufacturing the display device according to another exemplary embodiment of the present disclosure;

FIG. 7 is a cross-sectional view of a display device according to yet another exemplary embodiment of the present disclosure;

FIG. 8A through FIG. 8D are process diagrams for explaining a method of manufacturing the display device according to yet another exemplary embodiment of the present disclosure;

FIG. 9 is a cross-sectional view of a display device according to still another exemplary embodiment of the present disclosure; and

FIG. 10 is a cross-sectional view of a display device according to still another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

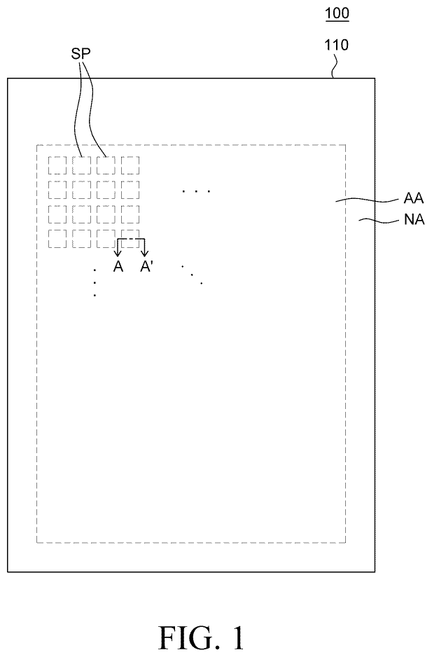

FIG. 1 is a schematic plan view of a display device according to an exemplary embodiment of the present disclosure. For the convenience of description, FIG. 1 illustrates only a substrate 110 and a plurality of sub-pixels among various components of a display device 100.

The substrate 110 is configured to support various components included in the display device 100 and, for example, may be made of an insulating material. For example, the substrate 110 may be made of glass, resin, or the like, may also be made of a material including polymer or plastic, or may be made of a material having flexibility. For example, the polymer film may be made of any one of polyimide (PI), polyethylene terephthalate (PET), acrylonitrile-butadiene-styrene copolymer(ABS), polymethyl methacrylate(PMMA), polyethylene naphthalate (PEN), polycarbonate (PC), polyethersulfone (PES), polyarylate (PAR), polysulfone (PSF), cyclic olefin copolymer(COC), triacetylcellulose(TAC) film, polyvinyl alcohol(PVA) film, and polystyrene(PS), and the present disclosure is not limited thereto.

The substrate 110 includes an active area AA and a non-active area NA.

The active area AA is an area where a plurality of sub-pixels SP is disposed and an image is displayed. Each of the plurality of sub-pixels SP is a unit that emits light. In each of the sub-pixels SP, a light emitting element and a driving circuit are formed. For example, the plurality of sub-pixels SP may include a red sub-pixel, a green sub-pixel, a blue sub-pixel and/or a white sub-pixel, but is not limited thereto. As another example, the plurality of sub-pixels SP may include sub-pixels of other colors such as cyan, magenta, yellow, etc., but is not limited thereto. Hereinafter, the plurality of sub-pixels SP will be described as including a red sub-pixel, a green sub-pixel and a blue sub-pixel, but is not limited thereto.

The non-active area NA is an area where no image is displayed, and, for example, at least one of various lines, driver ICs, and the like for driving the sub-pixels SP disposed in the active area AA may be disposed therein. For example, at least one of various ICs, such as a gate driver IC and a data driver IC, and various driving circuits may be disposed in the non-active area NA. As an example, at least a part of the non-active area NA may be located on a rear surface of the substrate 110, i.e., the surface on which no sub-pixel SP is disposed, or may be omitted, but is not limited thereto.

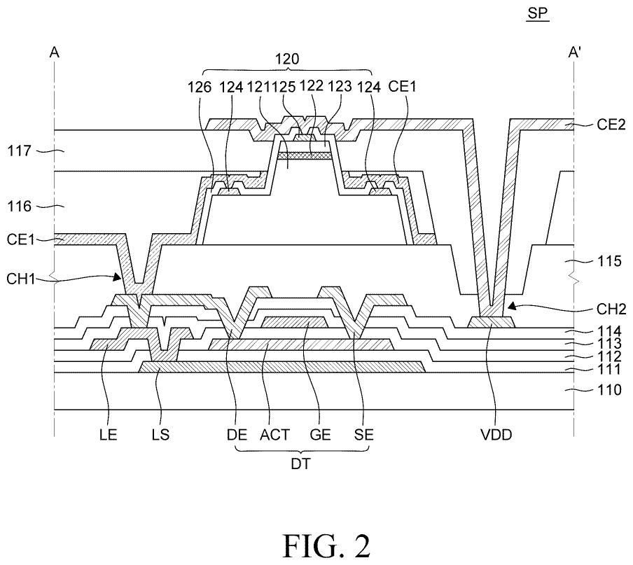

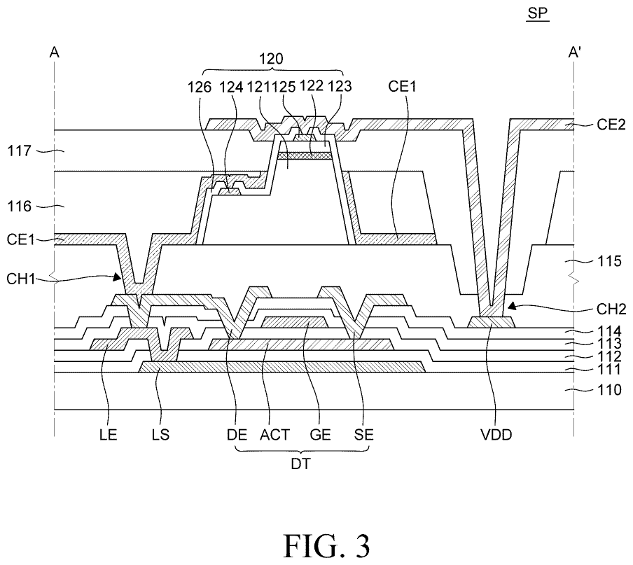

Hereinafter, the plurality of sub-pixels SP will be described in more detail with respect to FIG. 2 and FIG. 3.

FIG. 2 and FIG. 3 are cross-sectional views of the display device according to an exemplary embodiment of the present disclosure. Referring to FIG. 2 and FIG. 3, the display device 100 according to an exemplary embodiment of the present disclosure includes the substrate 110, a buffer layer 111, a gate insulating layer 112 and a first interlayer insulating layer 113, without being limited thereto. Also, the display device 100 includes a second interlayer insulating layer 114, an adhesive layer 115, a first planarization layer 116, a second planarization layer 117, a driving transistor DT and a light emitting element 120, without being limited thereto. Further, the display device 100 includes a first connection electrode CE1, a second connection electrode CE2, a light shielding layer LS and an auxiliary electrode LE, without being limited thereto. As an example, at least one of the above-mentioned components may be omitted. As another example, at least one other component may be further added.

Referring to FIG. 2 and FIG. 3, the light shielding layer LS is disposed on the substrate 110. The light shielding layer LS blocks light entering from below the substrate 110 to an active layer ACT of the driving transistor DT. Since the light shielding layer LS blocks light entering the active layer ACT of the driving transistor DT, a leakage current may be minimized or suppressed. The light shielding layer LS may be omitted according to the design.

The buffer layer 111 is disposed on the substrate 110 and the light shielding layer LS. The buffer layer 111 may suppress the permeation of moisture or impurities through the substrate 110. The buffer layer 111 may be a single layer or a plurality of layers made of, for example, silicon oxide (SiOx), silicon nitride (SiNx) and/or amorphous silicon (a-Si), but is not limited thereto. However, the buffer layer 111 may be omitted depending on the type of the substrate 110 or the type of the transistor, but is not limited thereto.

The driving transistor DT is disposed on the buffer layer 111. The driving transistor DT may include the active layer ACT, a gate electrode GE, a source electrode SE and a drain electrode DE.

The active layer ACT is disposed on the buffer layer 111. The active layer ACT may be made of a semiconductor material such as oxide semiconductor, amorphous silicon or polysilicon, compound semiconductor, etc., but is not limited thereto. For example, the oxide semiconductor material may be formed of any one of indium gallium zinc oxide (IGZO), indium zinc oxide (IZO), indium gallium tin oxide (IGTO), and indium gallium oxide (IGO), but is not limited thereto, or be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide.

The gate insulating layer 112 is disposed on the active layer ACT. The gate insulating layer 112 is an insulating layer configured to insulate the active layer ACT from the gate electrode GE. The gate insulating layer 112 may be a single layer or a plurality of layers made of inorganic layer, such as silicon oxide (SiOx) and/or silicon nitride (SiNx), but is not limited thereto.

The gate electrode GE is disposed on the gate insulating layer 112. As an example, the gate electrode GE may be electrically connected to the source electrode SE of the driving transistor DT, without being limited thereto. The gate electrode GE may be made of a conductive material, such as copper (Cu), aluminum (Al), molybdenum (Mo), nickel (Ni), titanium (Ti), chromium (Cr) or an alloy thereof, but is not limited thereto. Although the driving transistor DT in present disclosure is formed in top gate method, the driving transistor DT in present disclosure may be a bottom gate type or a dual gate type.

The first interlayer insulating layer 113 and the second interlayer insulating layer 114 are disposed on the gate electrode GE. The first interlayer insulating layer 113 and the second interlayer insulating layer 114 include contact holes for respectively connecting the source electrode SE and the drain electrode DE to a source region and drain region of the active layer ACT, and the channel region may be disposed between the source region and drain region of the active layer ACT and overlapped with the gate electrode GE. The first interlayer insulating layer 113 and the second interlayer insulating layer 114 are insulating layers configured to protect components disposed under the first interlayer insulating layer 113 and the second interlayer insulating layer 114. Each of the first interlayer insulating layer 113 and the second interlayer insulating layer 114 may be a single layer or a plurality of layers made of silicon oxide (SiOx) and/or silicon nitride (SiNx), but is not limited thereto.

The source electrode SE and the drain electrode DE electrically connected to the source region and drain region of the active layer ACT are disposed on the second interlayer insulating layer 114. Each of the source electrode SE and the drain electrode DE may be made of a conductive material, such as copper (Cu), aluminum (Al), molybdenum (Mo), nickel (Ni), titanium (Ti), chromium (Cr) or an alloy thereof, but is not limited thereto.

Meanwhile, it has been described in the present disclosure that the first interlayer insulating layer 113 and the second interlayer insulating layer 114, i.e., a plurality of insulating layers, are disposed between the gate electrode GE and the source and drain electrodes SE and DE. However, only one insulating layer may be disposed between the gate electrode GE and the source and drain electrodes SE and DE, but the present disclosure is not limited thereto. However, as shown in the drawings, a plurality of insulating layers, such as the first interlayer insulating layer 113 and the second interlayer insulating layer 114, is disposed between the gate electrode GE and the source and drain electrodes SE and DE. In this case, an electrode may be further formed between the first interlayer insulating layer 113 and the second interlayer insulating layer 114, and the further formed electrode may form a capacitor together with another component. The component may be disposed under the first interlayer insulating layer 113 or on the second interlayer insulating layer 114. But embodiments are not limited thereto. As another example, there may be no component between the first interlayer insulating layer 113 and the second interlayer insulating layer 114.

The auxiliary electrode LE is disposed on the gate insulating layer 112. The auxiliary electrode LE is configured to electrically connect the light shielding layer LS disposed under the buffer layer 111 to one of the source electrode SE and the drain electrode DE disposed on the second interlayer insulating layer 114. For example, the light shielding layer LS is electrically connected to one of the source electrode SE and the drain electrode DE through the auxiliary electrode LE a part of which passes through the buffer layer 111 and the gate insulating layer 112. Thus, the light shielding layer LS does not operate as a floating gate. Therefore, it is possible to reduce or minimize a change in a threshold voltage of the driving transistor DT, which is caused by the floated light shielding layer LS. Although the light shielding layer LS has been illustrated as being connected to the drain electrode DE, the light shielding layer LS may also be connected to the source electrode SE instead, but is not limited thereto. The light shielding layer LS may also be connected to another electrode or a wiring, etc. so as to have a constant voltage level during the driving of the driving transistor DT, without being limited thereto.

A power line VDD is disposed on the second interlayer insulating layer 114. Since the power line VDD together with the driving transistor DT is electrically connected to the light emitting element 120, the light emitting element 120 can emit light. The power line VDD may be made of a conductive material, such as copper (Cu), aluminum (Al), molybdenum (Mo), nickel (Ni), titanium (Ti), chromium (Cr) or an alloy thereof, but is not limited thereto.

The adhesive layer 115 is disposed on the driving transistor DT and the power line VDD. As an example, the adhesive layer 115 is coated on the entire surface of the substrate 110 to fix the light emitting element 120 disposed on the adhesive layer 115. The adhesive layer 115 may be made of a material selected from any one of, for example, adhesive polymers, epoxy resists, UV resins, polyimides, acrylates, urethanes and polydimethylsiloxane (PDMS), but is not limited thereto.

The light emitting element 120 is disposed on the adhesive layer 115. The light emitting element 120 is an element configured to emit light by an electric current. The light emitting element 120 may include light emitting elements 120 emitting red light, green light, blue light, and the like, and a combination thereof may implement light of various colors including white. But embodiments are not limited thereto. As an example, the light emitting element 120 may include light emitting elements 120 emitting other colors such as cyan, magenta, yellow, etc., and/or a combination thereof does not necessarily implement light of white color. For example, the light emitting element 120 may be a light emitting diode (LED),mini-LED or a micro-LED, but is not limited thereto.

The light emitting element 120 includes a first semiconductor layer 121, an emission layer 122, a second semiconductor layer 123, a first electrode 124, a second electrode 125 and an encapsulation layer 126, without being limited thereto. As an example, at least one of the above-mentioned components could be omitted, and/or one or more other components may be added.

The first semiconductor layer 121 is disposed on the adhesive layer 115, and the second semiconductor layer 123 is disposed over the first semiconductor layer 121 with emission layer 122 being disposed therebetween. The first semiconductor layer 121 and the second semiconductor layer 123 may be formed by doping a specific material with n-type impurities and/or p-type impurities. For example, the first semiconductor layer 121 and the second semiconductor layer 123 may be formed by doping a material, such as gallium nitride (GaN), indium aluminum phosphide (InAlP), gallium arsenide (GaAs), and the like, with p-type impurities or n-type impurities. Further, the p-type impurities may be magnesium (Mg), zinc (Zn), beryllium (Be), or the like, and the n-type impurities may be silicon (Si), germanium (Ge), tin (Sn), or the like, but they are not limited thereto.

A part of the first semiconductor layer 121 may be disposed to protrude to the outside of the second semiconductor layer 123. As an example, a part of the first semiconductor layer 121 may be disposed to protrude to the outside of the second semiconductor layer 123 in a lateral direction. The light emitting element 120 may have a lateral structure. In this structure, a top surface of the first semiconductor layer 121 is composed of a part overlapping the second semiconductor layer 123 and a part disposed on an outer side of the second semiconductor layer 123. However, the sizes and shapes of the first semiconductor layer 121 and the second semiconductor layer 123 may be modified in various ways, but the present disclosure is not limited thereto.

For example, referring to FIG. 2, the second semiconductor layer 123 is disposed in the center of the top surface of the first semiconductor layer 121. Also, the entire second semiconductor layer 123 may overlap the first semiconductor layer 121. The second semiconductor layer 123 may be disposed inside the first semiconductor layer 121. An edge of the second semiconductor layer 123 may be disposed inside an edge of the first semiconductor layer 121. The first semiconductor layer 121 may protrude to the outside of the second semiconductor layer 123 from all edges of the second semiconductor layer 123 in a plan view. The first semiconductor layer 121 may protrude to the outside of the second semiconductor layer 123 in all directions in the plan view. But embodiments are not limited thereto.

For example, referring to FIG. 3, the first semiconductor layer 121 may protrude to the outside of the second semiconductor layer 123 in some directions. The first semiconductor layer 121 may protrude to the outside of the second semiconductor layer 123 from some edges of the second semiconductor layer 123. The first semiconductor layer 121 may protrude to the outside of the second semiconductor layer 123 in a specific direction. As another example, the second semiconductor layer 123 may align with the first semiconductor layer 121 or even protrude to the outside of the first semiconductor layer 121 in a direction other than the specific direction.

The emission layer 122 is disposed between the first semiconductor layer 121 and the second semiconductor layer 123. The emission layer 122 may be supplied with holes and electrons from the first semiconductor layer 121 and the second semiconductor layer 123 and may emit light. The emission layer 122 may have a single-layer structure or multi-quantum well (MQW) structure. For example, the emission layer 122 may be implemented as a tandem structure with a plurality of light emitting layers stacked on top of each other. The light emitting element EL having the tandem structure may improve the luminance and lifespan of pixels, as an example, made of indium gallium nitride (InGaN), gallium nitride (GaN), or the like, but is not limited thereto.

At least one first electrode 124 is disposed on the first semiconductor layer 121. The first electrode 124 may be disposed on the top surface of the first semiconductor layer 121 exposed from the emission layer 122 and the second semiconductor layer 123. The first electrode 124 is configured to electrically connect the driving transistor DT to the first semiconductor layer 121. The first electrode 124 may be made of a transparent conductive material, such as indium tin oxide (ITO), indium zinc oxide (IZO), or the like. Alternatively, the first electrode 124 may be made of an opaque conductive material, such as titanium (Ti), gold (Au), silver (Ag), copper (Cu) or an alloy thereof. However, the present disclosure is not limited thereto.

The first electrode 124 may be offset to the outside of the light emitting element 120 in at least a part of the top surface of the first semiconductor layer 121 exposed from the emission layer 122 and the second semiconductor layer 123, without being limited thereto. The first electrode 124 may be spaced apart as far as possible from the second semiconductor layer 123 on which the second electrode 125 is disposed. Thus, an etching margin may be reduced when the first electrode 124 is formed. As an example, the first electrode 124 may be more spaced apart from the second semiconductor layer 123 than the center of the top surface of the first semiconductor layer 121 exposed from the second semiconductor layer 123, without being limited thereto. For example, a conductive layer covering the first semiconductor layer 121, the emission layer 122 and the second semiconductor layer 123 may be firstly formed. Then, the first electrode 124 and the second electrode 125 may be formed by etching the conductive layer. In this process, the first electrode 124 may be formed to be far from the second electrode 125 and the second semiconductor layer 123. Thus, even if a process error occurs when the first electrode 124 is formed, it is possible to reduce or minimize the possibility of forming the first electrode 124 on the second semiconductor layer 123. But embodiments are not limited thereto. As another example, the first electrode 124 and the second electrode 125 may be formed separately, for example, by a mask process, rather than by etching the same one conductive layer, without being limited thereto.

Further, since the first electrode 124 is spaced apart as far as possible from the second semiconductor layer 123 on which the second electrode 125 is disposed, the area of the emission layer 122 can be increased. If the first electrode 124 is disposed adjacent to an outer side of the light emitting element 120, the emission layer 122 may be formed in the other area excluding the first electrode 124. Also, the area of the emission layer 122 may be increased. If the first electrode 124 is disposed closer to the center of the light emitting element 120, the area of the emission layer 122, which needs to be spaced apart from the first electrode 124, may also be decreased. Thus, the light efficiency of the light emitting element 120 may be decreased. Therefore, the first electrode 124 may be disposed adjacent to the outer side of the light emitting element 120 to increase the area of the emission layer 122 and the light efficiency.

For example, referring to FIG. 2, the first electrode 124 disposed on both sides of the second semiconductor layer 123 may be offset to be far from the second semiconductor layer 123, for example, compared with the center of the exposed top surface of first semiconductor layer 121. The first electrode 124 disposed on the left side of the second semiconductor layer 123 may be offset to the left side on the exposed top surface of the first semiconductor layer 121. Also, the first electrode 124 may be disposed closer to the outer side of the light emitting element 120 than the second semiconductor layer 123. The first electrode 124 disposed on the right side of the second semiconductor layer 123 may be offset to the right side on the exposed top surface of the first semiconductor layer 121. Also, the first electrode 124 may be disposed closer to the outer side of the light emitting element 120 than the second semiconductor layer 123. Embodiments are not limited thereto. As an example, the first electrode 124 may be disposed on only one side of the second semiconductor layer 123.

For example, referring to FIG. 3, the first electrode 124 disposed on one side of the second semiconductor layer 123 may be offset to the one side on the exposed top surface of the first semiconductor layer 121, for example, compared with the center of the exposed top surface of the first semiconductor layer 121. Therefore, the first electrode 124 may be disposed closer to the outer side of the light emitting element 120 than the second semiconductor layer 123.

Then, the encapsulation layer 126 surrounding the first semiconductor layer 121, the emission layer 122, the second semiconductor layer 123, the first electrode 124 and the second electrode 125 is disposed. The encapsulation layer 126 may be made of an insulating material and thus may protect the first semiconductor layer 121, the emission layer 122 and the second semiconductor layer 123. Also, contact holes exposing the first electrode 124 and the second electrode 125 are formed in the encapsulation layer 126. Thus, the first electrode 124 and the second electrode 125 may be electrically connected to the first connection electrode CE1 and the second connection electrode CE2 to be formed later.

Meanwhile, it has been described in the present disclosure that the light emitting element 120 includes the first semiconductor layer 121, the emission layer 122, the second semiconductor layer 123, the first electrode 124, the second electrode 125 and the encapsulation layer 126. However, the light emitting element 120 may exclude the encapsulation layer 126 depending on design choice, but the present disclosure is not limited thereto.

The first connection electrode CE1 is disposed on the adhesive layer 115 and the light emitting element 120. The first connection electrode CE1 is configured to electrically connect the light emitting element 120 to the driving transistor DT. The first connection electrode CE1 may be electrically connected to any one of the source electrode SE and the drain electrode DE of the driving transistor DT through a first contact hole CH1 formed in the adhesive layer 115. For example, the first connection electrode CE1 may electrically connect the drain electrode DE of the driving transistor DT to the first electrode 124 and the first semiconductor layer 121 of the light emitting element 120. The first connection electrode CE1 may be disposed to cover at least a part of a side surface of the first semiconductor layer 121, at least a part of the first semiconductor layer 121 protruding to the outside of the second semiconductor layer 123, and at least a part of the first electrode 124. The first connection electrode CE1 may be disposed to be adjacent to or surround a lower side surface of the light emitting element 120.

The first planarization layer 116 and the second planarization layer 117 are disposed on the first connection electrode CE1 and the light emitting element 120 to protect the driving transistor DT and to planarize a step caused due to the driving transistor DT and the first connection electrode CE1. The first planarization layer 116 and the second planarization layer 117 may planarize an upper part of the substrate 110 on which the light emitting element 120 is disposed. The first planarization layer 116 and the second planarization layer 117 together with the adhesive layer 115 may fix the light emitting element 120 onto the substrate 110. Each of the first planarization layer 116 and the second planarization layer 117 may be a single layer or a plurality of layers made of, for example, a photo resist or an acryl-based organic material, acrylic resin, epoxy resin, phenolic resin, polyamides resin, unsaturated polyesters resin, polyphenylene resin, polyphenylene sulfides resin, and benzocyclobutene, but is not limited thereto.

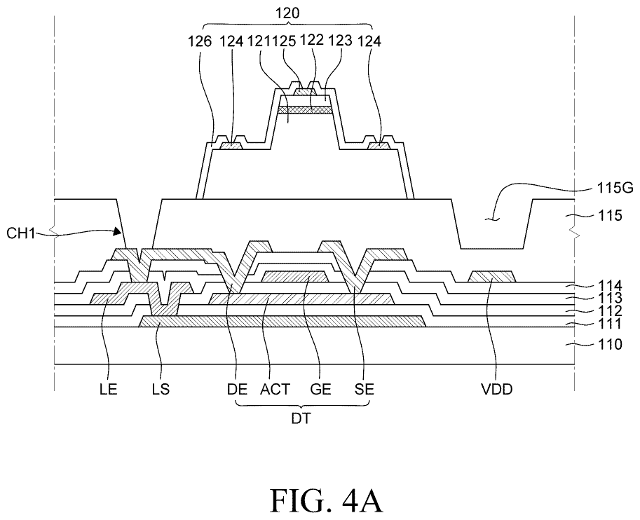

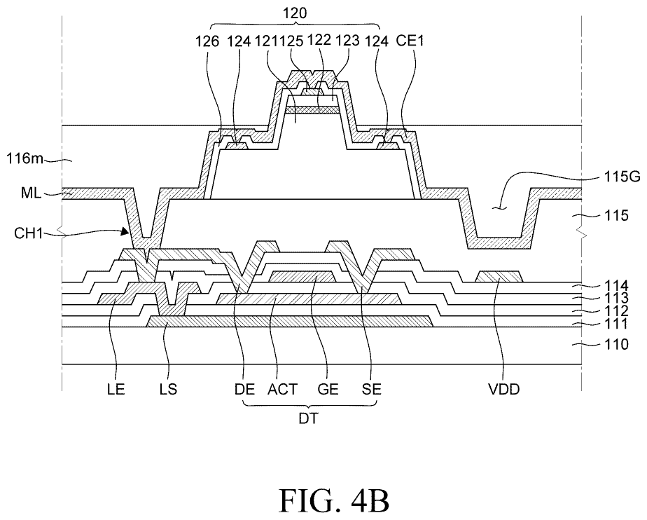

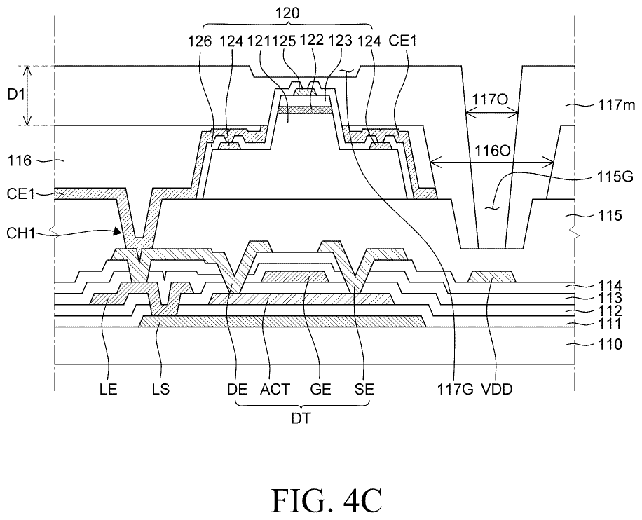

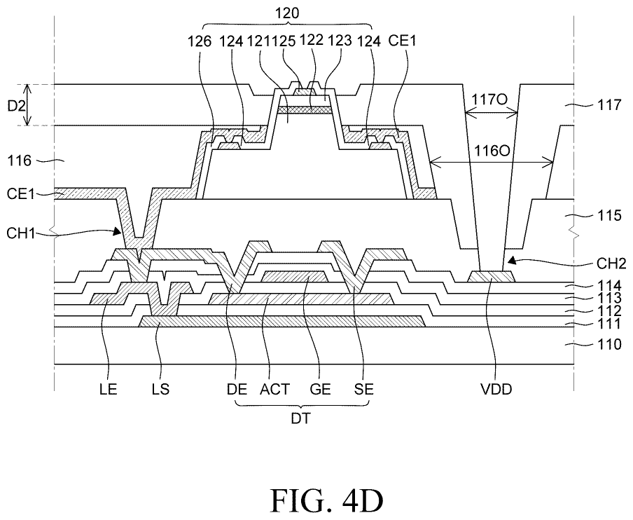

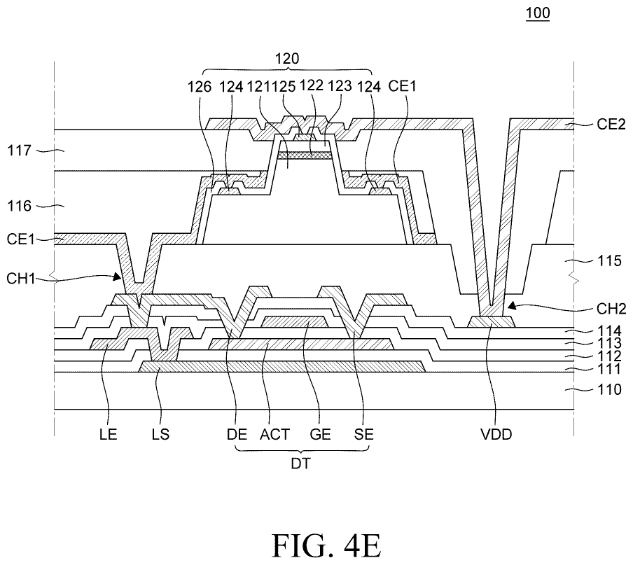

The first planarization layer 116 may have a smaller thickness than the first semiconductor layer 121 of the light emitting element 120. For example, a top surface of the first planarization layer 116 may be disposed under the emission layer 122. For example, a top surface of the first planarization layer 116 may be disposed above the first electrode 124 and/or the first connection electrode CE1 and under the emission layer 122. When the display device 100 is manufactured, the first planarization layer 116 may be used to self-align the first connection electrode CE1 to be connected only to the first semiconductor layer 121 and the first electrode 124. Also, a top surface of the second planarization layer 117 may be disposed higher than at least the emission layer 122 of the light emitting element 120. Further, the top surface of the second planarization layer 117 may be disposed equal to or lower than a top surface of the second semiconductor layer 123. For example, the top surface of the second planarization layer 117 corresponding to the light emitting element 120 may be disposed between a top surface of the emission layer 122 and the top surface of the second semiconductor layer 123. Alternatively, the top surface of the second planarization layer 117 may be disposed in the same plane as the top surface of the second semiconductor layer 123. Therefore, when the display device 100 is manufactured, the second planarization layer 117 may be used to self-align the second connection electrode CE2 to be connected only to the second semiconductor layer 123 and the second electrode 125. More details thereof will be described later with reference to FIG. 4A through FIG. 4E.

The second connection electrode CE2 is disposed on the second planarization layer 117. The second connection electrode CE2 is configured to electrically connect the light emitting element 120 to the power line VDD. The second connection electrode CE2 may be electrically connected to the power line VDD through a second contact hole CH2 formed in the second planarization layer 117, the first planarization layer 116 and the adhesive layer 115. Further, the second connection electrode CE2 is in contact with the second electrode 125 (e.g., a top surface thereof) exposed from the second planarization layer 117 so as to be electrically connected to the second electrode 125 and the second semiconductor layer 123.

Meanwhile, in the display device 100 according to an exemplary embodiment of the present disclosure, the light emitting element 120, the first connection electrode CE1 and the second connection electrode CE2 may be self-aligned. That is, the first connection electrode CE1 and the second connection electrode CE2 connected to the first electrode 124 and the second electrode 125 of the light emitting element 120 are self-aligned without a separate alignment process. Therefore, it is possible to reduce or minimize a short defect and secure a transfer margin.

Hereinafter, a process of forming the first connection electrode CE1 and the second connection electrode CE2 will be described with reference to FIG. 4A through FIG. 4E.

FIG. 4A through FIG. 4E are process diagrams for explaining a method of manufacturing the display device according to an exemplary embodiment of the present disclosure. FIG. 4A through FIG. 4C are process diagrams for explaining a process of forming the first connection electrode CE1, and FIG. 4D and FIG. 4E are process diagrams for explaining a process of forming the second connection electrode CE2.

Referring to FIG. 4A, the light emitting element 120 is transferred onto the adhesive layer 115. The light emitting element 120 may be grown on a separate wafter and then transferred onto the substrate 110. For example, the light emitting element 120 may be separated from the wafer by a laser lift-off (LLO) process, or the like and then transferred onto the adhesive layer 115. Herein, the adhesive layer 115 has adhesiveness and thus may fix the light emitting element 120 separated from the wafer and transferred onto the adhesive layer 115.

Herein, the light emitting element 120 transferred onto the substrate 110 may not include contact holes that expose the first electrode 124 and the second electrode 125 in the encapsulation layer 126. Before the light emitting element 120 is transferred onto the substrate 110, the encapsulation layer 126 covering all of the first semiconductor layer 121, the emission layer 122, the second semiconductor layer 123, the first electrode 124 and the second electrode 125 is formed in the light emitting element 120. Herein, the encapsulation layer 126 may cover all of the first electrode 124 and the second electrode 125, but may have a small thickness only in a part corresponding to the first electrode 124 and the second electrode 125. That is, the encapsulation layer 126 may have a greater thickness in the other part corresponding to side and top surfaces of the first semiconductor layer 121, a side surface of the emission layer 122, and side and top surfaces of the second semiconductor layer 123 than in the part corresponding to the first electrode 124 and the second electrode 125. But embodiments are not limited thereto. As an example, the encapsulation layer 126 may have uniform thickness even in the part corresponding to the first electrode 124 and the second electrode 125. As another example, the light emitting element 120 transferred onto the substrate 110 may already include contact holes that expose the first electrode 124 and the second electrode 125 in the encapsulation layer 126. As another example, the encapsulation layer 126 may be omitted.

After the light emitting element 120 in the above-described state is transferred onto the substrate 110, a contact hole may be formed in the encapsulation layer 126 by performing an etching process to the light emitting element 120. Specifically, as an example, in the light emitting element 120 in which only a part of the encapsulation layer 126 covering the first electrode 124 and the second electrode 125 has a small thickness, an etching process is performed to the encapsulation layer 126. Thus, contact holes exposing the first electrode 124 and the second electrode 125 may be formed in the encapsulation layer 126. Therefore, after the light emitting element 120 is transferred onto the substrate 110, the contact holes exposing the first electrode 124 and the second electrode 125 may be formed in the encapsulation layer 126.

Meanwhile, the light emitting element 120 may be transferred from the wafer onto the substrate 110 in various ways. For example, the light emitting element 120 may be transferred onto the substrate 110 by self-alignment. In self-alignment, the light emitting element 120 is self-aligned on a temporary substrate on which a plurality of alignment lines is formed and then, the temporary substrate is located on the substrate 110. Thereafter, the light emitting element 120 self-aligned on the temporary substrate may be transferred onto the substrate 110. Specifically, the plurality of alignment lines that generates an electric field may be formed on the temporary substrate, and the light emitting element 120 may be self-aligned on the temporary substrate by the electric field generated by the alignment lines. Further, in a state where the temporary substrate is disposed to face the substrate 110, a laser or the like is irradiated to the temporary substrate to transfer the light emitting element 120 from the temporary substrate onto the substrate 110. If self-alignment is performed as described above, a process of precisely aligning the light emitting element 120 is omitted. Therefore, it is possible to more easily transfer the light emitting element 120 onto the substrate 110.

Then, the first contact hole CH1 and a first groove 115G are formed in the adhesive layer 115, for example, through a mask process. The first contact hole CH1 exposing the drain electrode DE and the first groove 115G overlapping the power line VDD may be formed in the adhesive layer 115 by using a halftone mask, halftone masks can help simplify and reduce the overall fabrication process by enabling the creation of multi-level structures in a single etching step, which can lead to cost savings and improved throughput for manufacturing. In the first groove 115G, the power line VDD is not exposed from the adhesive layer 115. However, in a subsequent process, the second contact hole CH2 exposing the power line VDD is formed in the first groove 115G. Thus, the second connection electrode CE2 may be connected to the power line VDD.

Meanwhile, FIG. 4A illustrates that the first groove 115G is formed in a part of the adhesive layer 115 overlapping the power line VDD. However, the second contact hole CH2 exposing the power line VDD may be initially formed in the adhesive layer 115, but is not limited thereto.

Then, referring to FIG. 4B, a metal layer ML and a first planarization material layer 116m are formed throughout the entire surface of the substrate 110. The metal layer ML is formed on the light emitting element 120 throughout the entire surface of the substrate 110. The first planarization material layer 116m is formed to cover the metal layer ML. The metal layer ML may be formed to cover the adhesive layer 115 and the light emitting element 120. A part of the metal layer ML may be electrically connected to the drain electrode DE through the first contact hole CH1 formed in the adhesive layer 115.

Then, the first planarization material layer 116m may be formed to cover the metal layer ML. The first planarization material layer 116m is a layer of a material forming the first planarization layer 116, and may be formed as the first planarization layer 116 in a subsequent process. Herein, the first planarization material layer 116m is formed to have a smaller thickness than the light emitting element 120. An upper part of the light emitting element 120 may be disposed on an outer side of the first planarization material layer 116m. For example, the emission layer 122 and the second semiconductor layer 123 of the light emitting element 120 may be located above a top surface of the first planarization material layer 116m. Also, at least only a part of the first semiconductor layer 121 of the light emitting element 120 may be covered by the first planarization material layer 116m. That is, the first planarization material layer 116m may have a smaller thickness than the first semiconductor layer 121. Therefore, a part of the metal layer ML covering the emission layer 122 and the second semiconductor layer 123 may be exposed from the first planarization material layer 116m.

Meanwhile, it has been described in the present disclosure that the first planarization material layer 116m initially has a smaller thickness than the first semiconductor layer 121 of the light emitting element 120. However, the thickness of the first planarization material layer 116m may be regulated by performing, for example, an ashing process. For example, the first planarization material layer 116m may be formed to have a greater thickness than the first semiconductor layer 121 of the light emitting element 120. Then, an ashing process may be performed to the first planarization material layer 116m to reduce the overall thickness of the first planarization material layer 116m. Thus, the first planarization material layer 116m may be formed to have a smaller thickness than the first semiconductor layer 121, but is not limited thereto.

Referring to FIG. 4C, the first planarization layer 116 including a first opening 116O is formed by removing a part of the first planarization material layer 116m. The first opening 116O of the first planarization layer 116 may overlap the first groove 115G of the adhesive layer 115. A part of the metal layer ML covering the first groove 115G of the adhesive layer 115 may be exposed to the outside through the first opening 116O of the first planarization layer 116. The first opening 116O may overlap the second contact hole CH2 of the adhesive layer 115 to be formed in a subsequent process, and may serve as the second contact hole CH2 to expose the power line VDD.

Thereafter, the first connection electrode CE1 is formed by patterning a part of the metal layer ML exposed from the first planarization layer 116. A part of the metal layer ML surrounding the second electrode 125, the second semiconductor layer 123 and the emission layer 122 of the light emitting element 120 may be removed, for example, by wet etching or dry etching, without being limited thereto. Also, a part of the metal layer ML overlapping the first opening 116O of the first planarization layer 116 may be removed, for example, by wet etching or dry etching, without being limited thereto. Therefore, only a part of the metal layer ML covered by the first planarization layer 116 remains, and may serve as the first connection electrode CE1 surrounding the first semiconductor layer 121 under the first planarization layer 116.

In summary, the first planarization layer 116 is formed to have a smaller thickness than the first semiconductor layer 121 on the metal layer ML. As an example, the first planarization layer 116 is formed to have a greater thickness than a part of the metal layer ML overlapping the first electrode 124. The first planarization layer 116 is used as a mask to remove a part of the metal layer ML covering the second semiconductor layer 123 and the emission layer 122. Also, only a part of the metal layer ML covering the first semiconductor layer 121 remains to form the first connection electrode CE1. In this case, the first planarization layer 116 serves as a mask. Therefore, an uppermost part of the first connection electrode CE1 may be disposed in the same plane as the top surface of the first planarization layer 116. Also, a side surface of the first connection electrode CE1 may be disposed in the same plane as a side surface of the first planarization layer 116 in the first opening 116O.

The first connection electrode CE1 is not initially aligned corresponding to the first electrode 124 on a top surface of the first semiconductor layer 121 of the light emitting element 120. Instead, only the metal layer ML exposed from the first planarization layer 116 having a smaller thickness than the first semiconductor layer 121 of the light emitting element 120 may be simply removed to form the first connection electrode CE1 by self-alignment.

Meanwhile, as described above, if the light emitting element 120 is disposed by self-alignment, the first semiconductor layer 121 protruding from the second semiconductor layer 123 may be aligned in various directions in the light emitting element 120. As shown in FIG. 3, the light emitting element 120 may have an asymmetric structure in which the first semiconductor layer 121 protrudes only to one side of the second semiconductor layer 123. For example, the protruding first semiconductor layer 121 may be aligned to the left side of the light emitting element 120 as shown in FIG. 3, or the first semiconductor layer 121 may be aligned to the right side of the light emitting element 120. As for a display device in which the first connection electrode CE1 is formed through a general mask process, it may be difficult to connect the light emitting element 120, which is randomly disposed, to the first connection electrode CE1. Also, such a display device may be susceptible to a short defect. However, in the display device 100 according to an exemplary embodiment of the present disclosure, the first connection electrode CE1 is formed by self-alignment. Thus, the first connection electrode CE1 may be easily electrically connected to the light emitting element 120 regardless of an alignment direction of the light emitting element 120.

Then, referring to FIGS. 4C and 4D, a second planarization material layer 117m is formed on the first planarization layer 116. The second planarization material layer 117m is a material layer to be formed as the second planarization layer 117 in a subsequent process. The second planarization material layer 117m may be formed to cover the first planarization layer 116 and the emission layer 122, the second semiconductor layer 123 and the second electrode 125 of the light emitting element 120. Also, the second planarization material layer 117m may be formed to cover the first groove 115G of the adhesive layer 115 exposed in the first opening 116O of the first planarization layer 116.

Thereafter, a second opening 117O and a second groove 117G are formed in the second planarization material layer 117m, for example, through a mask process. The second opening 117O exposing the first groove 115G of the adhesive layer 115 may be formed in the second planarization material layer 117m, for example, by using a halftone mask. Also, the second groove 117G overlapping the second semiconductor layer 123 of the light emitting element 120 may be formed in the second planarization material layer 117m, for example, by using the halftone mask. The second opening 117O may be formed in the second planarization material layer 117m, and the second contact hole CH2 may be formed in the first groove 115G exposed through the second opening 117O in a subsequent process. Thus, the power line VDD may be connected to the second connection electrode CE2. Therefore, the first opening 116O overlapping the second contact hole CH2 of the adhesive layer 115 and the second opening 117O expose the power line VDD. Thus, they can serve as the second contact hole CH2.

Then, referring to FIG. 4E, the second planarization layer 117 and the second contact hole CH2 may be formed by performing, for example, an ashing process to the second planarization material layer 117m and the adhesive layer 115. The ashing process refers to a process by which plasm or the like including oxygen is used to decompose or remove an organic material such as a photo resist. By performing the ashing process to remove an upper part of the second planarization material layer 117m, the second electrode 125 of the light emitting element 120 may be exposed from a portion of the second planarization layer 117 where the second groove 117G is located. That is, a portion of the second planarization material layer 117m where the second groove 117G is located is removed by the ashing process, and a hole through which the second electrode 125 is exposed may be formed in the second planarization layer 117. Also, by performing the ashing process to remove a part of the adhesive layer 115 exposed in the first opening 116O and the second opening 117O and corresponding to the first groove 115G, the second contact hole CH2 exposing the power line VDD may be formed.

The ashing process may be performed to reduce the overall thickness of the second planarization layer 117 and reduce the thickness of a part of the adhesive layer 115 exposed from the second planarization layer 117. For example, before the ashing process, the second planarization material layer 117m may have a first thickness D1 as shown in FIG. 4C. After the ashing process, the second planarization layer 117 may have a second thickness D2 as shown in FIG. 4D. That is, by performing the ashing process, the thickness of the second planarization layer 117 may be decreased from the first thickness D1 to the second thickness D2 which is smaller than the first thickness D1. Likewise, an ashing process may be performed to reduce the overall thickness of a part of the adhesive layer 115 exposed in the first opening 116O and the second opening 117O. Therefore, the ashing process may be performed to reduce the thicknesses of the second planarization layer 117 and the adhesive layer 115. Thus, the second electrode 125 on the second semiconductor layer 123 may be exposed in the portion of the second planarization layer 117 where the second groove 117G is located, and the power line VDD may be exposed in the first groove 115G of the adhesive layer 115.

For example, the ashing process may be performed to entirely remove an upper part of the second planarization layer 117 until the top surface of the second electrode 125 on the second semiconductor layer 123 is exposed from the second planarization layer 117. That is, the ashing process may be performed until the top surface of the second electrode 125 on the second semiconductor layer 123 is exposed from the portion of the second planarization layer 117 where the second groove 117G is located. For example, the ashing process may be performed to remove a part of the adhesive layer 115 until the power line VDD is exposed in the first groove 115G of the adhesive layer 115. The ashing process may be performed until the power line VDD is exposed in the first groove 115G of the adhesive layer 115. Therefore, the ashing process may be performed to expose the power line VDD from the adhesive layer 115 and/or expose the second electrode 125 on second semiconductor layer 123 from the second planarization layer 117. Embodiments are not limited thereto. As an example, at least one of the power line VDD and the second electrode 125 may be not exposed even after the ashing process. In this case, a separate process for exposing the at least one of the power line VDD and the second electrode 125 may be further performed.

Finally, the second connection electrode CE2 is formed on the second planarization layer 117 so as to correspond to the second contact hole CH2 and the second semiconductor layer 123. The second connection electrode CE2 may be electrically connected to the power line VDD through the second contact hole CH2. Also, the second connection electrode CE2 may be in contact with the top surface of the second electrode 125 exposed from the second planarization layer 117 so as to be electrically connected to the second electrode 125 and the second semiconductor layer 123. Therefore, the ashing process may be performed to expose the second electrode 125 on the second semiconductor layer 123 of the light emitting element 120 and the power line VDD to the outside. Also, a metal layer may be formed throughout the entire surface of the substrate 110 and patterned on the second planarization layer 117 to form the second connection electrode CE2. Thus, the second connection electrode CE2 may be easily electrically connected to the second semiconductor layer 123 and the second electrode 125.

For example, in order to form a first connection electrode and a second connection electrode, an insulating layer covering a top surface of a first semiconductor layer, a side surface of an emission layer and a side surface and a part of a top surface of a second semiconductor layer may be formed. Then, a metal layer may be deposited and patterned on the insulating layer to simultaneously form the first connection electrode and the second connection electrode. However, in this case, the first connection electrode may be formed even on the top surface of the second semiconductor layer due to a process error or misalignment. Also, the second connection electrode may be formed even on the top surface of the first semiconductor layer, which may cause a short defect. Thus, when the first connection electrode and the second connection electrode are formed, a short defect may occur due to a process error. Therefore, it is necessary to secure a margin, taking into account the process error. Further, as the size of a light emitting element and the size of an electrode are reduced to a micro size, there is a limitation in coping with a short defect.

Therefore, in the display device 100 according to an exemplary embodiment of the present disclosure and the method of manufacturing the display device 100, the second connection electrode CE2 and the second semiconductor layer 123 of the light emitting element 120 may be formed by self-alignment. An ashing process may be performed to the second planarization layer 117 covering the second semiconductor layer 123 and the second electrode 125 of the light emitting element 120 to allow only the second semiconductor layer 123 and the second electrode 125 of the light emitting element 120 to be exposed from the second planarization layer 117. For example, by performing the ashing process to reduce the overall thickness of the second planarization layer 117, only the top surface of the second electrode 125 may be exposed to the outside of the second planarization layer 117. The ashing process may be performed only until the top surface of the second electrode 125 of the light emitting element 120 is exposed. Thus, the emission layer 122 and the first semiconductor layer 121 may not be exposed from the second planarization layer 117. The second connection electrode CE2 may be formed by forming and patterning the metal layer ML throughout the entire surface of the substrate 110 including the second planarization layer 117. Even in this case, the second connection electrode CE2 may be in contact with only the top surface of the second electrode 125 exposed from the second planarization layer 117. Also, the second connection electrode CE2 may be spaced apart from the first connection electrode CE1, the emission layer 122 and the first semiconductor layer 121 disposed under the second planarization layer 117. Since the second connection electrode CE2 is in contact with only the top surface of the second electrode 125, it is not necessary to secure a process margin, taking into account the positions of the first semiconductor layer 121 and the first connection electrode CE1 when the second connection electrode CE2 is formed. Therefore, in the display device 100 according to an exemplary embodiment of the present disclosure and the method of manufacturing the display device 100, the light emitting element 120 and the second connection electrode CE2 are self-aligned through an ashing process. Thus, it is possible to reduce or minimize a short defect caused by a process error.

Therefore, in the display device 100 according to an exemplary embodiment of the present disclosure and the method of manufacturing the display device 100, the first connection electrode CE1 and the first semiconductor layer 121 of the light emitting element 120 may be formed by self-alignment. Specifically, the metal layer ML may be formed first to cover the light emitting element 120, and the first planarization layer 116 may be formed to cover the metal layer ML. In this case, the first planarization layer 116 may be formed to have a smaller thickness than the first semiconductor layer 121 of the light emitting element 120. Also, the emission layer 122 and the second semiconductor layer 123 of the light emitting element 120 may be disposed above the top surface of the first planarization layer 116. Therefore, only a part of the metal layer ML covering the emission layer 122 and the second semiconductor layer 123 of the light emitting element 120 may be exposed from the first planarization layer 116. Further, the first planarization layer 116 may be used as a mask to remove only a part of the metal layer ML exposed from the first planarization layer 116. Therefore, only a part of the metal layer ML covered by the first planarization layer 116 may remain to form the first connection electrode CE1. That is, only a part of the metal layer ML surrounding the first semiconductor layer 121 and the first electrode 124 of the light emitting element 120 may remain to form the first connection electrode CE1. Therefore, the positions of the first semiconductor layer 121 and the first connection electrode CE1 are not precisely aligned. Instead, the first planarization layer 116 having a smaller thickness than the first semiconductor layer 121 may be used to self-align the first connection electrode CE1 with the first semiconductor layer 121 and the first electrode 124. Therefore, in the display device 100 according to an exemplary embodiment of the present disclosure and the method of manufacturing the display device 100, the first planarization layer 116 having a smaller thickness than the first semiconductor layer 121 may be used to form the first connection electrode CE1 by self-alignment. Thus, it is possible to reduce or minimize a short defect occurring when the first connection electrode CE1 is connected even to the second semiconductor layer 123.

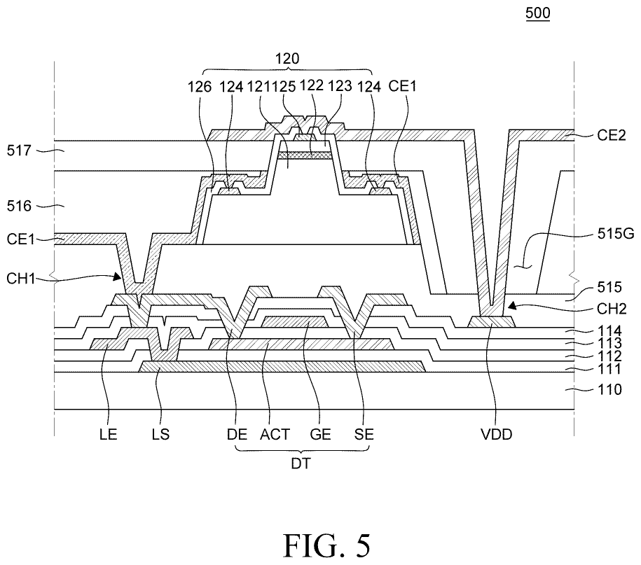

FIG. 5 is a cross-sectional view of a display device according to another exemplary embodiment of the present disclosure. A display device 500 shown in FIG. 5 is substantially the same as the display device 100 shown in FIG. 1 through FIG. 3 except an adhesive layer 515, a first planarization layer 516, the first connection electrode CE1 and a second planarization layer 517. Therefore, a repeated description thereof will be omitted or briefly given.

Referring to FIG. 5, a first groove 515G overlapping the power line VDD is disposed in the adhesive layer 515. The first groove 515G of the adhesive layer 515 may be formed in a region where the first connection electrode CE1 is not disposed. Further, the second contact hole CH2 connected to the power line VDD and the second connection electrode CE2 may be disposed in the first groove 515G of the adhesive layer 515.

The first connection electrode CE1 is disposed corresponding to an edge of the first groove 515G of the adhesive layer 515. The first connection electrode CE1 may be formed only to a top surface of the adhesive layer 515 corresponding to the edge of the first groove 515G of the adhesive layer 515, but may not be disposed inside the first groove 515G.

An edge of the first planarization layer 516 is disposed inside the first groove 515G of the adhesive layer 515. The first planarization layer 516 is disposed to cover a side wall of the adhesive layer 515 forming the first groove 515G of the adhesive layer 515. The first planarization layer 516 may be disposed to cover the edge of the first groove 515G.

The second planarization layer 517 may not include a separate groove overlapping the second semiconductor layer 123 of the light emitting element 120, but may have a flat top surface. A top surface of the second planarization layer 517 may be disposed equal to the top surface of the second semiconductor layer 123 or may be disposed between the top surface and the bottom surface of the second semiconductor layer 123. Thus, the second electrode 125 on the second semiconductor layer 123 may be exposed from the second planarization layer 517. That is, the top surface of the second planarization layer 517 may be disposed substantially equal to the top surface of the second semiconductor layer 123.

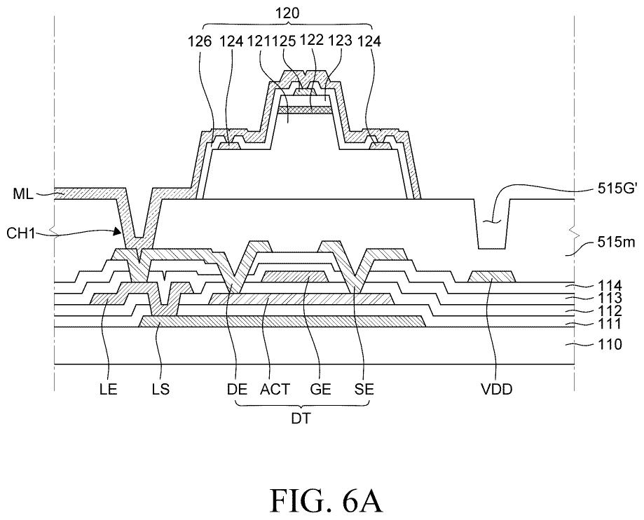

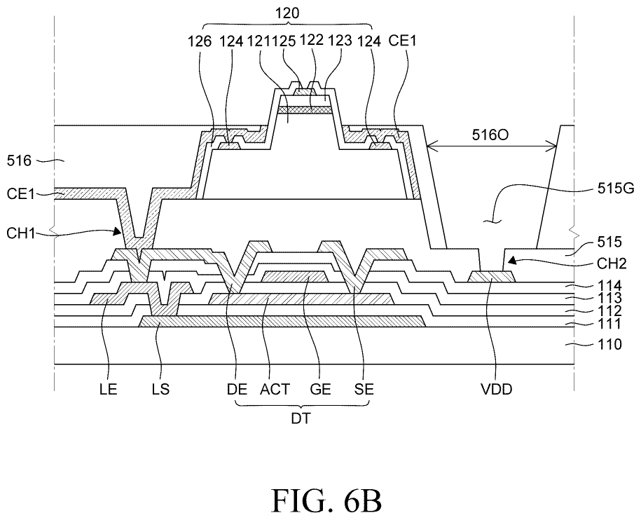

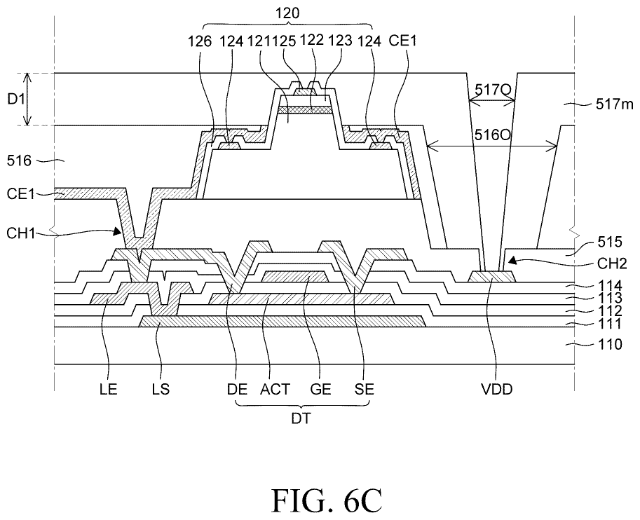

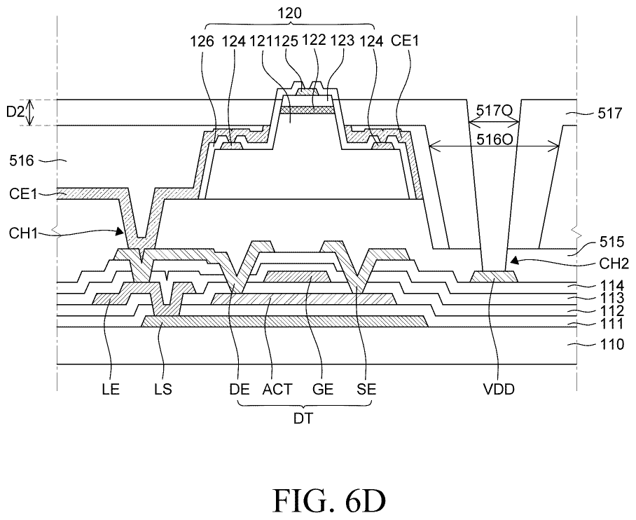

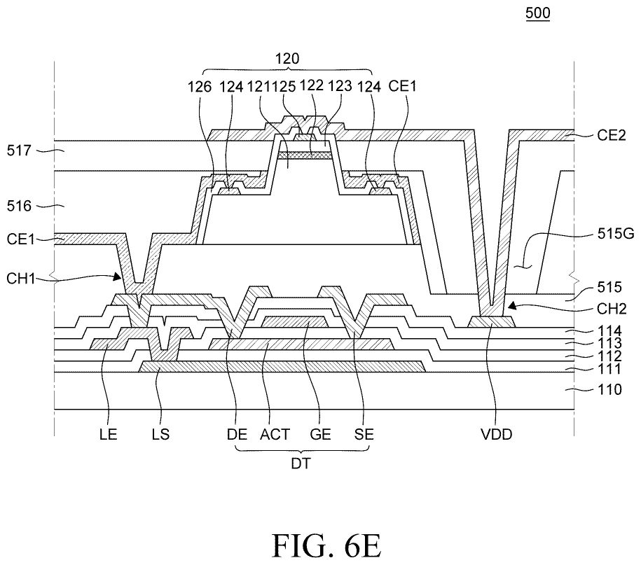

Hereinafter, a method of manufacturing the display device 500 according to another exemplary embodiment of the present disclosure will be described with reference to FIG. 6A through FIG. 6E.

FIG. 6A through FIG. 6E are process diagrams for explaining a method of manufacturing the display device according to another exemplary embodiment of the present disclosure. FIG. 6A and FIG. 6B are process diagrams for explaining a process of forming the first connection electrode CE1, and FIG. 6C through FIG. 6E are process diagrams for explaining a process of forming the second connection electrode CE2.

Referring to FIG. 6A, the light emitting element 120 is transferred onto an adhesive material layer 515m, and the first contact hole CH1 and a first initial groove 515G′ are formed in the adhesive material layer 515m. The adhesive material layer 515m is a material layer to be formed as the adhesive layer 515 in a subsequent process. The first contact hole CH1 is a contact hole that exposes the drain electrode DE from the adhesive material layer 515m. The first initial groove 515G′ overlapping the power line VDD may be formed as the second contact hole CH2 in a subsequent process.

Then, the metal layer ML is formed on the adhesive material layer 515m and the light emitting element 120. The metal layer ML formed throughout the entire surface of the substrate 110 is patterned in a region overlapping the first initial groove 515G′ of the adhesive material layer 515m. Thus, only a part of the metal layer ML overlapping the light emitting element 120 and the first contact hole CH1 may remain. That is, only a part of the metal layer ML covering the first semiconductor layer 121, the emission layer 122 and the second semiconductor layer 123 of the light emitting element 120 and a part of the metal layer ML disposed in the first contact hole CH1 may remain on the substrate 110. That is, the first initial groove 515G′ of the adhesive material layer 515m may be spaced apart from the metal layer ML and may be exposed to the outside. The metal layer ML may be patterned again to be formed as the first connection electrode CE1 in a subsequent process.

Referring to FIG. 6B, a mask process is performed to the adhesive material layer 515m exposed from the metal layer ML to form the adhesive layer 515 including the second contact hole CH2. The mask process for patterning a part of the adhesive material layer 515m, for example, by dry etching may be performed to remove a part of the first initial groove 515G′ of the adhesive material layer 515m exposed from the metal layer ML. Also, a part of the first initial groove 515G′ may be removed to form the second contact hole CH2. Further, a part of the adhesive layer 515 disposed around the first initial groove 515G′ may be removed to form a new first groove 515G. Therefore, the second contact hole CH2 may be formed by removing a part of the first initial groove 515G′. Also, a new first groove 515G may be formed by removing a part of an upper part of the adhesive layer 515 disposed around the first initial groove 515G′. In this case, the second contact hole CH2 may be disposed inside the first groove 515G. Therefore, only a part of the metal layer ML corresponding to the power line VDD and the first initial groove 515G′ is removed and then, an etching process (e.g., a dry etching process) is performed to remove a part of the adhesive material layer 515m exposed from the metal layer ML. Thus, it is possible to form the adhesive layer 515 including the second contact hole CH2 that exposes the power line VDD.

In this case, the metal layer ML serves as a mask. Thus, an edge of the metal layer ML may correspond to the first groove 515G of the adhesive layer 515. An edge of the first groove 515G of the adhesive layer 515 may overlap the edge of the metal layer ML, and the metal layer ML may not be disposed inside the first groove 515G. The metal layer ML may be disposed only on the adhesive layer 515 except the first groove 515G.

Meanwhile, it has been described in the present disclosure that the second contact hole CH2 of the adhesive layer 515 is formed by dry etching. Alternatively, an ashing process for reducing the overall thickness of the adhesive material layer 515m exposed from the metal layer ML may be performed to form the second contact hole CH2 and the first groove 515G. However, the present disclosure is not limited thereto.

Then, the first planarization layer 516 is formed on the adhesive layer 515, the light emitting element 120 and the metal layer ML. Also, a first opening 516O is formed in the first planarization layer 516 by removing a part of the first planarization layer 516 overlapping the second contact hole CH2. The first planarization layer 516 may be formed to cover the metal layer ML and the light emitting element 120. Also, in a subsequent process, a part of the first planarization layer 516 covering the second contact hole CH2 of the adhesive layer 515 and the power line VDD may be removed. Thus, the first opening 516O may be formed to be connected to the second connection electrode CE2 and the power line VDD. Therefore, when the first planarization layer 516 is formed, the first opening 516O may be formed to overlap the second contact hole CH2.

Herein, the first planarization layer 516 may be formed to have a smaller thickness than the light emitting element 120. Also, the metal layer ML covering the upper part of the light emitting element 120 may be exposed from the first planarization layer 516. For example, the first planarization layer 516 may have a smaller thickness than the first semiconductor layer 121. Therefore, a part of the metal layer ML covering the emission layer 122 and the second semiconductor layer 123 of the light emitting element 120 may be exposed from the first planarization layer 516.

Thereafter, the first connection electrode CE1 is formed by patterning a part of the metal layer ML exposed from the first planarization layer 516. A part of the metal layer ML surrounding the second electrode 125, the second semiconductor layer 123 and the emission layer 122 of the light emitting element 120 may be removed, for example, by wet etching. Therefore, only a part of the metal layer ML covered by the first planarization layer 516 remains, and may serve as the first connection electrode CE1. The first connection electrode CE1 surrounds the first semiconductor layer 121 and the first electrode 124 under the first planarization layer 516. Therefore, the first planarization layer 516 having a smaller thickness than the first semiconductor layer 121 may be used to remove a part of the metal layer ML covering the second electrode 125, the second semiconductor layer 123 and the emission layer 122. Also, the other part of the metal layer ML covering the first semiconductor layer 121 and the first electrode 124 may remain. Thus, the first connection electrode CE1 and the first electrode 124 on the first semiconductor layer 121 may be self-aligned.

Referring to FIG. 6C, a second planarization material layer 517m is formed on the first planarization layer 516, and a second opening 517O is formed in the second planarization material layer 517m, for example, through a mask process. The second planarization material layer 517m may be formed to cover the upper part of the light emitting element 120. The second planarization material layer 517m may have a first thickness D1 and may cover the second electrode 125, the second semiconductor layer 123 and the emission layer 122 of the light emitting element 120. Further, the second planarization material layer 517m may be patterned, for example, by dry etching, to form the second opening 517O overlapping the first opening 516O of the first planarization layer 516 and the second contact hole CH2 of the adhesive layer 515. Thus, the second contact hole CH2 and the power line VDD may be exposed in the second opening 517O to the outside.

Then, referring to FIG. 6D, the second planarization layer 517 is formed, for example, by performing an ashing process to the second planarization material layer 517m in which the second opening 517O is formed. The ashing process may be performed to remove an upper part of the second planarization material layer 517m. As a result, the second planarization layer 517 having a second thickness D2 which is smaller than the first thickness D1 may be formed. Further, the ashing process may be performed to reduce the overall thickness of the second planarization layer 517, and, thus, the upper part of the light emitting element 120 may be exposed from the second planarization layer 517. For example, by performing the ashing process, the second electrode 125 of the light emitting element 120 may be exposed to the outside of the second planarization layer 517. Alternatively, the second electrode 125 and only an upper part of the second semiconductor layer 123 may be exposed to the outside of the second planarization layer 517.

Thereafter, referring to FIG. 6E, the second connection electrode CE2 is formed on the second planarization layer 517. The second connection electrode CE2 may be connected to the second electrode 125 on the second semiconductor layer 123 of the light emitting element 120 exposed from the second planarization layer 517. Also, the second connection electrode CE2 may be connected to the power line VDD exposed in the second opening 517O of the second planarization layer 517 and the second contact hole CH2 of the adhesive layer 515.

Therefore, in the display device 500 according to another exemplary embodiment of the present disclosure and the method of manufacturing the display device 500, the metal layer ML may be used as a mask. Thus, it is possible to easily form the second contact hole CH2 that exposes the power line VDD from the adhesive layer 515. Also, the second contact hole CH2 that exposes the power line VDD may be formed by removing a part of the metal layer ML overlapping the power line VDD and etching the adhesive layer 515 exposed from the metal layer ML. Therefore, the second contact hole CH2 is not formed by precisely aligning the position of the power line VDD. Instead, an etching process may be performed to a part of the adhesive layer 515 exposed from the metal layer ML to easily form the second contact hole CH2 that exposes the power line VDD.

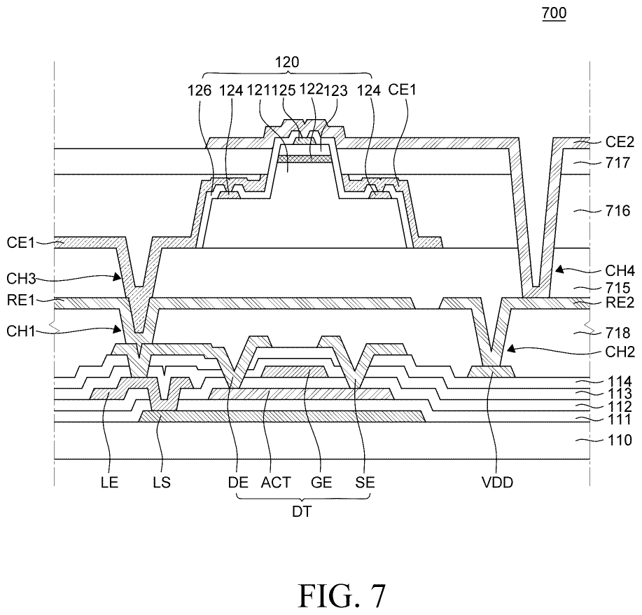

FIG. 7 is a cross-sectional view of a display device according to yet another exemplary embodiment of the present disclosure. A display device 700 shown in FIG. 7 is substantially the same as the display device 500 shown in FIG. 5 except further including a passivation layer 718, a first reflective electrode RE1 and a second reflective electrode RE2. Therefore, a repeated description thereof will be omitted or briefly given.

Referring to FIG. 7, the passivation layer 718 is disposed on the driving transistor DT and the power line VDD. The passivation layer 718 may be a single layer or a plurality of layers. Also, the passivation layer 718 may be made of, for example, a photo resist or an acryl-based organic material or an inorganic material such as silicon oxide (SiOx) and/or silicon nitride (SiNx), but is not limited thereto.

The first reflective electrode RE1 and the second reflective electrode RE2 spaced apart from each other may be disposed between the passivation layer 718 and an adhesive layer 715. The first reflective electrode RE1 serves as a reflective layer to electrically connect the driving transistor DT to the first connection electrode CE1 and to reflect light emitted from the light emitting element 120 to above the light emitting element 120. The second reflective electrode RE2 serves as a reflective layer to electrically connect the power line VDD to the second connection electrode CE2 and to reflect light emitted from the light emitting element 120 to above the light emitting element 120. The first reflective electrode RE1 and the second reflective electrode RE2 are made of a conductive material having high reflectivity and thus may reflect light emitted from the light emitting element 120 to above the light emitting element 120.

The first reflective electrode RE1 may be electrically connected to the drain electrode DE of the driving transistor DT through the first contact hole CH1 of the passivation layer 718. The second reflective electrode RE2 may be electrically connected to the power line VDD through the second contact hole CH2 of the passivation layer 718.

Further, the first reflective electrode RE1 and the first connection electrode CE1 may be electrically connected to each other through a third contact hole CH3 of the adhesive layer 715. Furthermore, the second reflective electrode RE2 and the second connection electrode CE2 may be electrically connected to each other through a fourth contact hole CH4 of the adhesive layer 715.

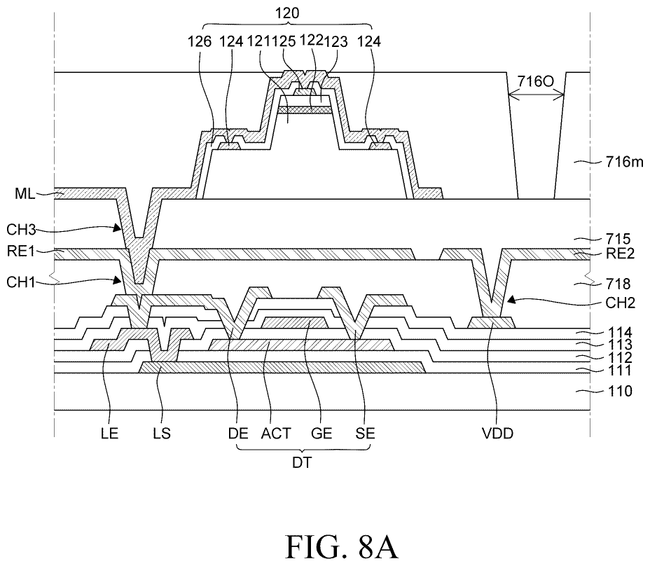

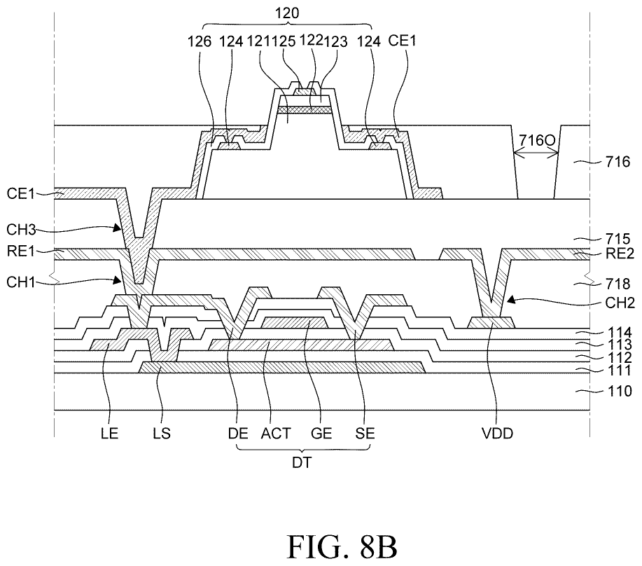

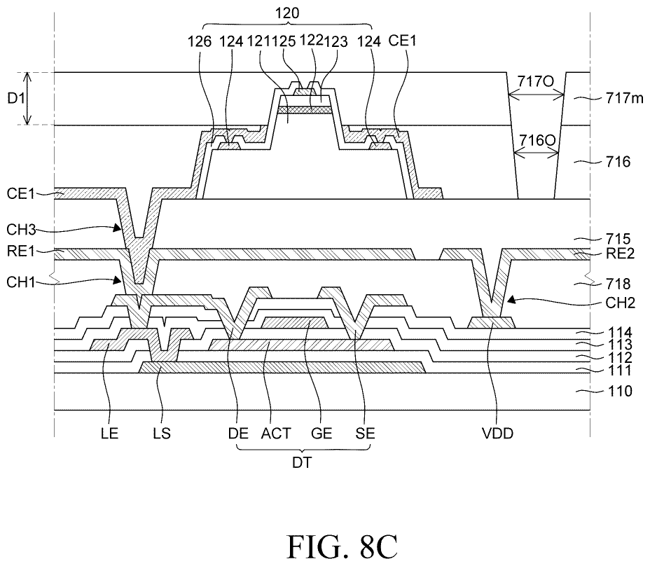

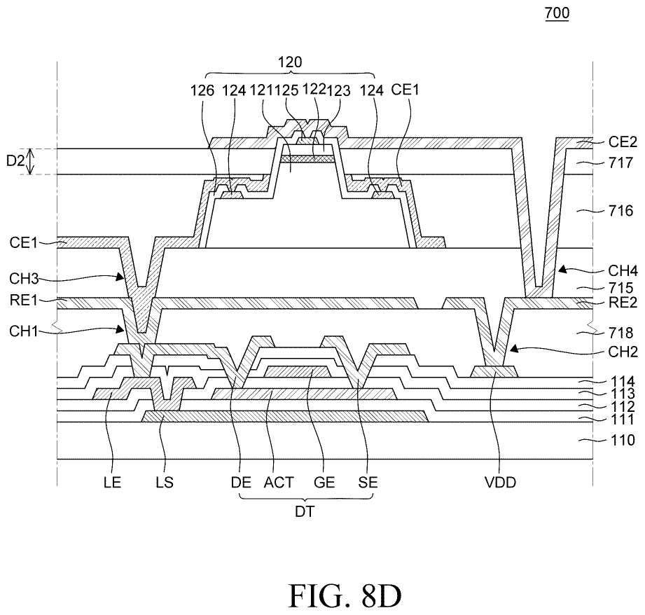

Hereinafter, a method of manufacturing the display device 700 according to yet another exemplary embodiment of the present disclosure will be described with reference to FIG. 8A through FIG. 8D.

FIG. 8A through FIG. 8D are process diagrams for explaining a method of manufacturing the display device according to yet another exemplary embodiment of the present disclosure. FIG. 8A and FIG. 8B are process diagrams for explaining a process of forming the first connection electrode CE1, and FIG. 8C and FIG. 8D are process diagrams for explaining a process of forming the second connection electrode CE2.

Referring to FIG. 8A, the first reflective electrode RE1 and the second reflective electrode RE2 are formed on the passivation layer 718. Also, the adhesive layer 715 is formed on the first reflective electrode RE1 and the second reflective electrode RE2. Then, the light emitting element 120 is transferred onto the adhesive layer 715 and the third contact hole CH3 is formed in the adhesive layer 715. The first reflective electrode RE1 connected to the drain electrode DE of the driving transistor DT may be exposed in the third contact hole CH3.

Then, the metal layer ML is formed on the light emitting element 120 and the adhesive layer 715. The metal layer ML may be patterned in a region overlapping the second reflective electrode RE2, and may be formed to overlap the light emitting element 120, the first contact hole CH1 and the third contact hole CH3. The metal layer ML may not overlap the second reflective electrode RE2, but may overlap the light emitting element 120 and the first reflective electrode RE1. The metal layer ML may be disposed to cover the first semiconductor layer 121, the emission layer 122 and the second semiconductor layer 123 of the light emitting element 120. Also, the metal layer ML may be electrically connected to the first reflective electrode RE1 through the third contact hole CH3.

Thereafter, a first planarization material layer 716m is formed on the light emitting element 120 and the metal layer ML. Also, a first opening 716O is formed in the first planarization material layer 716m. First, the first planarization material layer 716m may be formed to cover the light emitting element 120, the metal layer ML and the adhesive layer 715. Then, a part of the first planarization material layer 716m overlapping the second reflective electrode RE2 may be removed to form the first opening 716O. The first opening 716O may overlap the second reflective electrode RE2, and a part of the adhesive layer 715 may be exposed in the first opening 716O.

Then, referring to FIG. 8B, an ashing process is performed to the first planarization material layer 716m to form a first planarization layer 716. By performing the ashing process to the first planarization material layer 716m, the metal layer ML covering the upper part of the light emitting element 120 may be exposed from first planarization layer 716. The overall thickness of the first planarization layer 716 may be reduced by the ashing process. A part of the metal layer ML covering the emission layer 122 and the second semiconductor layer 123 of the light emitting element 120 may be exposed from the first planarization layer 716 whose thickness is reduced. That is, the ashing process may be performed in order for the first planarization layer 716 to have a smaller thickness than the first semiconductor layer 121 of the light emitting element 120.

Thereafter, the metal layer ML exposed from the first planarization layer 716 is removed. The metal layer ML exposed from the first planarization layer 716 may be patterned, for example, by wet etching, and, thus, the upper part of the light emitting element 120 may be exposed. Since a part of the metal layer ML disposed above a top surface of the first planarization layer 716 is removed, the second semiconductor layer 123 and the emission layer 122 disposed at the upper part of the light emitting element 120 may be exposed to the outside. Therefore, only a part of the metal layer ML covered by the first planarization layer 716 and surrounding the first semiconductor layer 121 of the light emitting element 120 remains, and may serve as the first connection electrode CE1.

Referring to FIG. 8C, a second planarization material layer 717m having a first thickness D1 is formed on the first planarization layer 716. Also, a second opening 717O is formed in the second planarization material layer 717m. The second planarization material layer 717m may be formed to cover the second semiconductor layer 123 and the emission layer 122 of the light emitting element 120 and the first planarization layer 716. Further, the second opening 717O may be formed to overlap the first opening 716O of the first planarization layer 716.

Then, the fourth contact hole CH4 is formed by removing a part of the adhesive layer 715 exposed in the first opening 716O of the first planarization layer 716 and the second opening 717O of the second planarization material layer 717m. The second planarization material layer 717m may be used as a mask to pattern a part of the adhesive layer 715. Thus, the fourth contact hole CH4 that exposes the second reflective electrode RE2 may be formed.

Thereafter, referring to FIG. 8D, an ashing process is performed to the second planarization material layer 717m to form a second planarization layer 717 having a second thickness D2 which is smaller than the first thickness D1. By performing ashing process to the second planarization material layer 717m, it is possible to form the second planarization layer 717 whose overall thickness is reduced. Also, it is possible to expose the second semiconductor layer 123 of the light emitting element 120 from the second planarization layer 717.

Then, the second connection electrode CE2 is formed on the second planarization layer 717. The second connection electrode CE2 may be connected to the top surface of the second semiconductor layer 123 of the light emitting element 120 exposed from the second planarization layer 717. Also, the second connection electrode CE2 may be connected to the second reflective electrode RE2 exposed in the second opening 717O of the second planarization layer 717, the first opening 716O of the first planarization layer 716 and the fourth contact hole CH4 of the adhesive layer 715. Therefore, the second semiconductor layer 123 of the light emitting element 120 may be electrically connected to the power line VDD through the second connection electrode CE2 and the second reflective electrode RE2.

Meanwhile, it has been described in the present disclosure that the process of forming the fourth contact hole CH4 of the adhesive layer 715 and the ashing process for the second planarization layer 717 are performed separately. However, the process of forming the fourth contact hole CH4 and the ashing process for the second planarization layer 717 may be performed simultaneously. For example, a part of the adhesive layer 715 exposed in the first opening 716O of the first planarization layer 716 and the second opening 717O of the second planarization material layer 717m and the second planarization material layer 717m may be ashed simultaneously. Thus, the fourth contact hole CH4 and the second planarization layer 717 may be formed simultaneously. However, the present disclosure is not limited thereto.

In the display device 700 according to yet another exemplary embodiment of the present disclosure and the method of manufacturing the display device 700, the first reflective electrode RE1 and the second reflective electrode RE2 are formed. Thus, it is possible to improve the light efficiency of the display device 700. The first reflective electrode RE1 and the second reflective electrode RE2 made of a conductive material having high reflectivity may be disposed under the light emitting element 120. A part of light emitted from the light emitting element 120 may travel to below the substrate 110. The first reflective electrode RE1 and the second reflective electrode RE2 may reflect the part of light to above the substrate 110 back and thus improve the light efficiency of the display device 700. In this case, the first reflective electrode RE1 and the second reflective electrode RE2 may not only serve as reflective plates to simply reflect light, but also serve as electrodes to drive the light emitting element 120. For example, the first reflective electrode RE1 may be disposed between the passivation layer 718 and the adhesive layer 715 to electrically connect the first connection electrode CE1 to the drain electrode DE of the driving transistor DT. The second reflective electrode RE2 may be disposed between the passivation layer 718 and the adhesive layer 715 to electrically connect the second connection electrode CE2 to the power line VDD. Therefore, in the display device 700 according to yet another exemplary embodiment of the present disclosure, the first reflective electrode RE1 and the second reflective electrode RE2 are used to improve the light efficiency of the display device 700. Also, the light emitting element 120 may be driven by connecting the light emitting element 120 to the driving transistor DT and the power line VDD. But embodiments are not limited thereto. As an example, at least one of the first reflective electrode RE1 and the second reflective electrode RE2 may be omitted. As another example, at least one of the first reflective electrode RE1 and the second reflective electrode RE2 may not be connected to the first connection electrode CE1 or the second connection electrode CE2. In this case, the at least one of the first reflective electrode RE1 and the second reflective electrode RE2 may be formed of an insulating material.

Also, in the display device 700 according to yet another exemplary embodiment of the present disclosure and the method of manufacturing the display device 700, the ashing process is performed to control the thickness of the first planarization layer 716. Thus, only the emission layer 122, the second semiconductor layer 123 and the second electrode 125 of the light emitting element 120 may be exposed from the first planarization layer 716. The first planarization material layer 716m may be formed on the light emitting element 120 and the metal layer ML. If the first planarization material layer 716m has a greater thickness than the first semiconductor layer 121 of the light emitting element 120, the metal layer ML exposed from the first planarization material layer 716m may be removed to form the first connection electrode CE1. In this case, the first connection electrode CE1 may be formed from the first semiconductor layer 121 to the emission layer 122. Alternatively, the first connection electrode CE1 may be formed even on the first semiconductor layer 121, the emission layer 122, the second semiconductor layer 123 and the second electrode 125. Thus, a short defect may occur. Accordingly, an ashing process may be performed to the first planarization material layer 716m in order for the first planarization layer 716 to have a smaller thickness than the first semiconductor layer 121. Therefore, in the display device 700 according to yet another exemplary embodiment of the present disclosure and the method of manufacturing the display device 700, the thickness of the first planarization layer 716 is regulated by performing an ashing process. Thus, when the metal layer ML is etched, only the metal layer ML covering the first semiconductor layer 121 may remain. Also, it is possible to reduce or minimize a short defect occurring when the first connection electrode CE1 is formed even on the emission layer 122 or the second semiconductor layer 123.

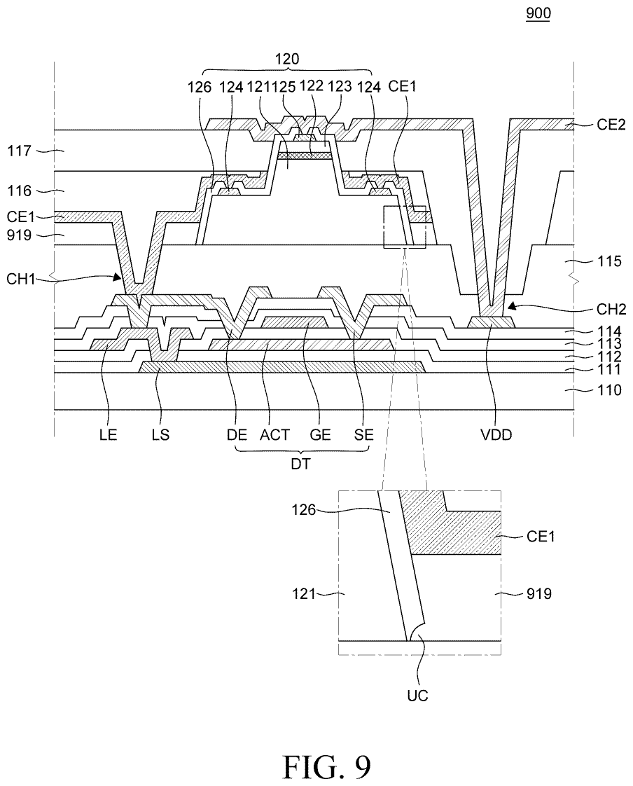

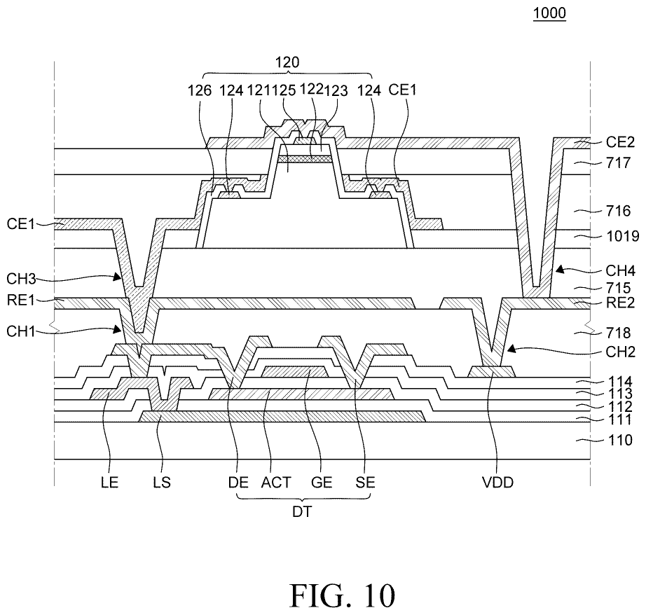

FIG. 9 is a cross-sectional view of a display device according to still another exemplary embodiment of the present disclosure. FIG. 10 is a cross-sectional view of a display device according to still another exemplary embodiment of the present disclosure. A display device 900 shown in FIG. 9 is substantially the same as the display device 100 shown in FIG. 1 through FIG. 3 except further including an insulating layer 919. Therefore, a repeated description thereof will be omitted or briefly given. Also, a display device 1000 shown in FIG. 10 is substantially the same as the display device 700 shown in FIG. 7 except further including an insulating layer 1019. Therefore, a repeated description thereof will be omitted or briefly given.

Referring to FIG. 9 and FIG. 10, the insulating layer 919 or 1019 is further disposed on the adhesive layer 115 or 715 so as to surround the lower side surface of the light emitting element 120. The insulating layer 919 or 1019 may be disposed on the adhesive layer 115 or 715 so as to surround a lower side surface of the first semiconductor layer 121 extending from a bottom surface of the first semiconductor layer 121 of the light emitting element 120.

When the display device 900 or 1000 is manufactured, the light emitting element 120 may be grown on a wafer and then separated from the wafer. Thereafter, the light emitting element 120 may be transferred onto the adhesive layer 115 or 715. In this case, while the light emitting element 120 is separated from the wafer, a part of a lower edge of the light emitting element 120 may be lifted off. Thus, an undercut structure UC may be formed at an edge of a bottom surface of the light emitting element 120. For example, when the light emitting element 120 is separated from the wafer, a part of a lower edge of the encapsulation layer 126 of the light emitting element 120 may be lifted off and an undercut structure UC may be formed.

If the first connection electrode CE1 is formed to surround a side surface of the encapsulation layer 126, the undercut structure UC may cause a disconnection defect of the first connection electrode CE1 around the undercut structure UC. Thus, before the first connection electrode CE1 is formed, the insulating layer 919 or 1019 may be further formed to surround a lower side surface of the encapsulation layer 126 and fill in the undercut structure UC. Therefore, the undercut structure UC and the first connection electrode CE1 may be spaced apart from each other. Also, it is possible to reduce or minimize disconnection of the first connection electrode CE1 caused by the undercut structure UC.

For example, referring to FIG. 9 with FIG. 4A and FIG. 4B, the light emitting element 120 may be transferred onto the adhesive layer 115 and the insulating layer 919 may be formed to surround a lower side surface of the light emitting element 120. Then, the metal layer ML may be formed on the insulating layer 919 and the light emitting element 120 to perform a subsequent process. Therefore, the insulating layer 919 may be first formed to surround a lower part of the light emitting element 120 before forming the metal layer ML to be formed as the first connection electrode CE1.

For example, referring to FIG. 10 with FIG. 8A, the light emitting element 120 may be transferred onto the adhesive layer 715 and the insulating layer 1019 may be formed to surround the lower side surface of the light emitting element 120. Then, the metal layer ML and the first planarization material layer 716m may be formed on the insulating layer 1019 and the light emitting element 120 to perform a subsequent process. Therefore, the insulating layer 1019 may be first formed to surround the lower part of the light emitting element 120 before forming the metal layer ML to be formed as the first connection electrode CE1.

Meanwhile, the insulating layers 919 and 1019 shown in FIG. 9 and FIG. 10, respectively, may also be used when the display device 500 shown in FIG. 5 as well as the display device 100 shown in FIG. 1 through FIG. 3 and the display device 700 shown in FIG. 7 is manufactured. However, the present disclosure is not limited thereto.

Therefore, in the display device 900 or 1000 according to still another exemplary embodiment of the present disclosure, the insulating layer 919 or 1019 is formed to compensate for the undercut structure UC at the lower side surface of the light emitting element 120. Thus, it is possible to suppress a disconnection defect of the first connection electrode CE1 caused by the undercut structure UC. While the light emitting element 120 is separated from the wafer and transferred onto the adhesive layer 115 or 715, the lower part of the light emitting element 120 may be lifted off. Thus, an undercut structure UC may be formed at the lower part of the light emitting element 120. For example, an undercut structure UC may be formed at a part of the lower edge of the encapsulation layer 126 or even a part of the lower edge of the first semiconductor layer 121. Then, if the first connection electrode CE1 is formed directly on the undercut structure UC, the undercut structure UC may cause disconnection of the first connection electrode CE1. Therefore, in the display device 900 or 1000 according to still another exemplary embodiment of the present disclosure, the insulating layer 919 or 1019 is first formed to fill in an empty space due to the undercut structure UC before the first connection electrode CE1 is formed. Accordingly, it is possible to separate the first connection electrode CE1 from the undercut structure UC and stably form the first connection electrode CE1 without disconnection.

The exemplary embodiments of the present disclosure can also be described as follows:

According to an aspect of the present disclosure, there is provided a display device. The display device includes a substrate in which a plurality of sub-pixels is defined, a light emitting element disposed on each of the plurality of sub-pixels, a first connection electrode surrounding a first semiconductor layer disposed at a lower part of the light emitting element, a second connection electrode in contact with a top surface of the light emitting element, a first planarization layer disposed between the first connection electrode and the second connection electrode and having a smaller thickness than the first semiconductor layer, and a second planarization layer disposed between the first planarization layer and the second connection electrode.

An uppermost part of the first connection electrode may be disposed in the same plane as a top surface of the first planarization layer.

A side surface of the first connection electrode may be disposed in the same plane as a side surface of the first planarization layer.

The light emitting element may further include an emission layer disposed on the first semiconductor layer, and a second semiconductor layer disposed on the emission layer and connected to the second connection electrode, and the first semiconductor layer protrudes to an outside of the second semiconductor layer from all edges of the second semiconductor layer, and a top surface of the second planarization layer may be disposed equal to or lower than a top surface of the second semiconductor layer.

The display device may further include an adhesive layer disposed under the light emitting element, and a power line disposed under the adhesive layer, the adhesive layer may include a first groove overlapping the power line and a contact hole overlapping the first groove.

An edge of the first connection electrode may correspond to an edge of the first groove, and an edge of the first planarization layer may be disposed in the first groove.

The display device may further include a passivation layer disposed between the adhesive layer and the power line, a first reflective electrode disposed between the adhesive layer and the passivation layer, and a second reflective electrode disposed between the adhesive layer and the passivation layer and spaced apart from the first reflective electrode.

According to an aspect of the present disclosure, there is provided a method of manufacturing a display device. The method of manufacturing a display device includes a process of transferring a light emitting element on an adhesive layer, a process of forming a metal layer on the light emitting element, a process of forming a first planarization layer having a smaller thickness than a first semiconductor layer of the light emitting element on the light emitting element and the metal layer, and a process of forming a first connection electrode by etching the metal layer exposed from the first planarization layer.

The process of forming a first planarization layer may further include a process of forming a first planarization material layer on the metal layer, and a process of forming the first planarization layer by performing an ashing process to the first planarization material layer, and the first planarization material layer has a greater thickness than the first semiconductor layer.

The method of manufacturing a display device may further include a process of forming a groove in the adhesive layer, the process of forming a metal layer may further include a process of removing a part of the metal layer corresponding to the groove.

The process of forming a first planarization layer further may include a process of removing a part of the first planarization layer corresponding to the groove.

The method of manufacturing a display device may further include a process of forming a second planarization material layer on the first planarization layer, the light emitting element and the first connection electrode, and a process of forming a second planarization layer by performing an ashing process to the second planarization material layer, a top surface of the second planarization material layer may be disposed above a top surface of the light emitting element, and a top surface of the second planarization layer may be disposed in the same plane as the top surface of the light emitting element or disposed below the top surface of the light emitting element.

The method of manufacturing a display device may further include a process of forming a contact hole in a part of the adhesive layer exposed from the metal layer and corresponding to the groove.

The process of forming a contact hole in the adhesive layer and the ashing process for the second planarization material layer may be performed simultaneously.

The process of forming a contact hole in the adhesive layer may be performed before the process of forming a first planarization layer.

In the process of forming a contact hole in the adhesive layer, the contact hole may be prepared by performing an ashing process to the adhesive layer.

The method of manufacturing a display device may further include a process of forming an opening in the second planarization layer so as to correspond to the contact hole of the adhesive layer, and a process of forming a second connection electrode on the second planarization layer and the contact hole, the second connection electrode may be in contact with a top surface of the light emitting element exposed from the second planarization layer.

The method of manufacturing a display device may further include a process of forming a first reflective electrode and a second reflective electrode to be spaced apart from each other on a substrate, and a process of forming the adhesive layer on the first reflective electrode and the second reflective electrode.

The method of manufacturing a display device may further include a process of forming an insulating layer on the adhesive layer so as to surround a lower side surface of the light emitting element before the process of forming a metal layer, the light emitting element may include an undercut structure at a lower edge of the light emitting element, and the insulating layer may be configured to fill in the undercut structure at the lower side surface of the light emitting element.

It will be apparent to those skilled in the art that various modifications and variations can be made in the display device and the method of manufacturing the same of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a substrate in which a plurality of sub-pixels is defined;
a light emitting element disposed in each of the plurality of sub-pixels;
a first connection electrode adjacent to and electrically connected to a first semiconductor layer disposed at a lower part of the light emitting element;
a second connection electrode in contact with a top surface of the light emitting element;
a first planarization layer disposed between the first connection electrode and the second connection electrode, and a top surface of the first planarization layer is lower than a top surface of the first semiconductor layer; and
a second planarization layer disposed between the first planarization layer and the second connection electrode.

2. The display device according to claim 1, wherein an uppermost part of the first connection electrode is disposed in the same plane as the top surface of the first planarization layer.

3. The display device according to claim 1, wherein a side surface of the first connection electrode is disposed in the same plane as a side surface of the first planarization layer.

4. The display device according to claim 1, wherein the light emitting element further includes:
an emission layer disposed on the first semiconductor layer; and
a second semiconductor layer disposed on the emission layer and electrically connected to the second connection electrode, and
the first semiconductor layer protrudes to an outside of the second semiconductor layer in a lateral direction.

5. The display device according to claim 4, wherein a top surface of the second planarization layer is disposed equal to or lower than a top surface of the second semiconductor layer.

6. The display device according to claim 4, wherein the first semiconductor layer protrudes to an outside of the second semiconductor layer from all edges of the second semiconductor layer in a horizontal direction.

7. The display device according to claim 4, wherein the first connection electrode is electrically connected to a first electrode disposed on a top surface of the first semiconductor layer exposed from the emission layer and the second semiconductor layer.

8. The display device according to claim 7, wherein the first electrode is offset to the outside of the light emitting element compared with a center of the top surface of the first semiconductor layer exposed from the emission layer and the second semiconductor layer.

9. The display device according to claim 1, wherein the first connection electrode is configured to electrically connect a driving transistor of the sub-pixel to the first semiconductor layer.

10. The display device according to claim 1, wherein the first connection electrode is configured to surround the first semiconductor layer.

11. The display device according to claim 1, further comprising:
an adhesive layer disposed under the light emitting element; and
a power line disposed under the adhesive layer,
wherein the adhesive layer includes a first groove overlapping the power line and a contact hole below and overlapping the first groove.

12. The display device according to claim 11, wherein an edge of the first connection electrode corresponds to an edge of the first groove, and
an edge of the first planarization layer is disposed in the first groove.

13. The display device according to claim 11, further comprising:
a passivation layer disposed between the adhesive layer and the power line;
a first reflective electrode disposed between the adhesive layer and the passivation layer.

14. The display device according to claim 13, wherein the first reflective electrode is configured to electrically connect the first connection electrode to a driving transistor of the sub-pixel.

15. The display device according to claim 11, wherein the second connection electrode is electrically connected to the power line.

16. The display device according to claim 1, further comprising:
an insulating layer surrounds a lower side surface of the light emitting element under the first connection electrode.

17. The display device according to claim 16, wherein the light emitting element includes an undercut structure at a lower edge of the light emitting element, filled with the insulating layer.

18. A method of manufacturing a display device, comprising:
a process of transferring a light emitting element on an adhesive layer;
a process of forming a metal layer on the light emitting element;
a process of forming a first planarization layer having a top surface lower than a top surface of a first semiconductor layer of the light emitting element on the light emitting element and the metal layer; and
a process of forming a first connection electrode by etching the metal layer exposed from the first planarization layer, the first connection electrode being electrically connected to the first semiconductor layer.

19. The method of manufacturing a display device according to claim 18, wherein the process of forming a first planarization layer further includes:
a process of forming a first planarization material layer on the metal layer, a top surface of the first planarization material layer being higher than the top surface of the first semiconductor layer; and
a process of forming the first planarization layer by performing an ashing process to the first planarization material layer.

20. The method of manufacturing a display device according to claim 18, further comprising:
a process of forming a groove in the adhesive layer,
wherein the process of forming a metal layer further includes a process of removing a part of the metal layer corresponding to the groove.

21. The method of manufacturing a display device according to claim 20, wherein the process of forming a first planarization layer further includes a process of removing a part of the first planarization layer corresponding to the groove.

22. The method of manufacturing a display device according to claim 20, further comprising:
a process of forming a second planarization material layer on the first planarization layer, the light emitting element and the first connection electrode; and
a process of forming a second planarization layer by performing an ashing process to the second planarization material layer,
wherein a top surface of the second planarization material layer is disposed above a top surface of the light emitting element, and
a top surface of the second planarization layer is disposed in the same plane as the top surface of the light emitting element or disposed below the top surface of the light emitting element.

23. The method of manufacturing a display device according to claim 20, further comprising:
a process of forming a contact hole in a part of the adhesive layer exposed from the metal layer and corresponding to the groove.

24. The method of manufacturing a display device according to claim 23, wherein the process of forming a contact hole in the adhesive layer and the ashing process for the second planarization material layer are performed simultaneously.

25. The method of manufacturing a display device according to claim 23, wherein the process of forming a contact hole in the adhesive layer is performed before the process of forming a first planarization layer.

26. The method of manufacturing a display device according to claim 23, in the process of forming a contact hole in the adhesive layer, the contact hole is prepared by performing an ashing process to the adhesive layer.

27. The method of manufacturing a display device according to claim 23, further comprising:
a process of forming an opening in the second planarization layer so as to correspond to the contact hole of the adhesive layer; and
a process of forming a second connection electrode on the second planarization layer and the contact hole,
wherein the second connection electrode is in contact with a top surface of the light emitting element exposed from the second planarization layer.

28. The method of manufacturing a display device according to claim 18, further comprising:
a process of forming a first reflective electrode on a substrate; and
a process of forming the adhesive layer on the first reflective electrode.

29. The method of manufacturing a display device according to claim 18, further comprising:
a process of forming an insulating layer on the adhesive layer so as to surround a lower side surface of the light emitting element before the process of forming a metal layer,
wherein the light emitting element includes an undercut structure at a lower edge of the light emitting element, and
the insulating layer is configured to fill in the undercut structure at the lower side surface of the light emitting element.
